(19) United States
(12) Patent Application Publication
(10) Pub. No.: US 2011/0058586 A1
(43) Pub. Date: Mar. 10, 2011

(54) NITRIDE SEMICONDUCTOR LASER

(76) Inventors: Toshiyuki Takizawa, Kyoto (JP); Tetsuzo Ueda, Osaka (JP)

(21) Appl. No.: 12/991,649

(22) PCT Filed: Jan. 21, 2009
(86) PCT No.: PCT/JP2009/000216

§ 371 Date: Nov. 8, 2010

(30) Foreign Application Priority Data
May 19, 2008 (JP) 2008-131320

(51) Int. Cl. H01S 5/323; H01S 5/22; H01S 5/343; B82Y 99/00

(52) U.S. Cl. 372/45.01; 977/951

(57) ABSTRACT

A projection/recess structure is formed on a base substrate, and a layered structure of a nitride semiconductor laser is formed on the projection/recess structure. InGaN used for an active layer has an In intake efficiency and a growth rate that greatly vary with the plane direction. By use of this characteristic, an active layer structure low in In content and small in well layer thickness can be formed at a light-outgoing end facet by one-time crystal growth, and thus the transition wavelength of the active layer near the light-outgoing end facet can be shortened. As a result, since optical damage due to light absorption at the light-outgoing end facet can be greatly reduced, a nitride semiconductor laser capable of performing high light-output operation can be implemented.

### TECHNICAL FIELD

The present disclosure relates to a nitride semiconductor laser.

### BACKGROUND ART

In recent years, blue-violet semiconductor lasers constructed of nitride semiconductors have been actively researched and developed. Since the wavelength of the light from blue-violet semiconductor lasers is short, the recording density can be greatly increased by using such lasers as light sources for optical recording. At present, therefore, products such as Blu-ray discs using blue-violet semiconductor lasers for reading and writing are becoming available in the market. A nitride semiconductor laser structure is implemented by forming a ridge waveguide on a double-hetero structure having InGaN as the active layer and then forming end facets by cleavage (see Non-Patent Document 1, for example). Currently, with the aim of expanding the capabilities such as high-speed read from and write to Blu-ray discs, technological development for further high light-output operation is underway.

NON-PATENT DOCUMENT 1: Shuji Nakamura, Masayuki Senoh, Shin-ichi Nagahama, Naruhito Iwasa, Takao Yamada, Toshio Matsushita, Hiroyuki Kiyoku, Yasunobu Sugimoto, Takuya Kozaki, Hitoshi Umemoto, Masahiko Sano, and Kazuyuki Chocho, “InGaN/GaN/AlGaN-based laser diodes with modulation-doped strained-layer superlattices grown on an epitaxially laterally overgrown GaN substrate,” Appl. Phys. Lett. Vol. 72 (1998)

### SUMMARY OF THE INVENTION

### Technical Problem

Further high light output is necessary for achieving widespread use of nitride semiconductor lasers in the society. In general, with increase of the light output of a semiconductor laser, the element causes optical damage, impairing the reliability seriously. The major factor for this is degradation at the light-outgoing end facet. At the end facet, the periodicity of crystal is disturbed, causing formation of an interface state in the forbidden band and reduction of the forbidden band, that is, increase of the transition wavelength. Part of laser light is absorbed by the interface state and the reduced forbidden band at the end facet, and as a result, the end facet is locally heated, causing optical damage. This is a major impediment to achievement of increase of the light output of nitride semiconductor lasers.

In view of the technical problem described above, an objective of the present invention is preventing the transition wavelength of a laser from increasing at its light-outgoing end facet, thereby to reduce optical damage at the end facet.

If only the problem of optical damage at the light-outgoing end facet is solved, nitride semiconductor lasers using nitride semiconductors, which are stable materials much higher in heat resistance than conventional compound semiconductors such as gallium arsenide, can obtain a high light-output characteristic far outstripping that of conventional red semiconductor lasers.

Once high light output is achieved, the nitride semiconductor lasers are expected to exhibit further high functions. An example of lasers having a high function is a distributed feedback laser for use in holographic memory and the like, in which a high single-wavelength characteristic can be obtained by distributed feedback using a diffraction grating. Also, a variety of applications are expected, including electromagnetic wave generation and wavelength conversion using the high output and the single-wavelength characteristic.

### Solution to the Problem

To solve the problem described above, according to the present invention, by making good use of plane direction dependence of crystal growth that is unique to nitride semiconductors, a high-output nitride semiconductor laser is implemented with low cost and excellent mass-productivity with little increasing the number of steps.

Specific configurations of the present invention are as follows.

The nitride semiconductor laser of the present invention includes: a substrate; a projection/recess structure on the substrate; a semiconductor multilayer film formed on the projection/recess structure; an optical waveguide structure formed on the semiconductor multilayer film; and two end facets including a light-outgoing end facet, wherein the semiconductor multilayer film includes a first semiconductor layer, an active layer formed on the first semiconductor layer, and a second semiconductor layer formed on the active layer, the active layer and the optical waveguide structure are placed between the two end facets, the cross-sectional shape of a structure including the substrate and the projection/recess structure taken along a plane parallel to a principal surface of the substrate is different between a light-outgoing end facet-adjacent region and a region other than the light-outgoing end facet-adjacent region, and a transition wavelength of the active layer right under the optical waveguide structure is shorter in the light-outgoing end facet-adjacent region than in the region other than the light-outgoing end facet-adjacent region.

With the above configuration, by changing the cross-sectional shape of the structure including the substrate and the projection/recess structure between the light-outgoing end facet-adjacent region and the other region, the transition wavelength of the active layer can be shortened in the light-outgoing end facet-adjacent region. This makes it possible to reduce light absorption of laser light significantly in the light-outgoing end facet-adjacent region, and thus reduce optical damage at the end facet. As a result, high light output can be achieved. Note that the state where the cross-sectional shape is different between the two regions includes a state where no section exists in one region when the two regions are cut along a plane parallel to the principal surface of the substrate.

In the nitride semiconductor laser of the present invention, preferably, at an interface between the first semiconductor layer and the active layer, a plane direction is different between the light-outgoing end facet-adjacent region and the region other than the light-outgoing end facet-adjacent region.

With the above configuration, the transition wavelength of the active layer formed on the first semiconductor layer can be changed between the light-outgoing end facet-adjacent region and the other region. As a result, the transition wavelength of the active layer can be shortened in the light-outgoing end facet-adjacent region. This makes it possible to reduce light absorption of laser light significantly in the light-outgoing end facet-adjacent region, and thus reduce optical damage at the end facet. Thus, high light output can be achieved.

In the nitride semiconductor laser of the present invention, preferably, the active layer has a multiple quantum well structure including a well layer and a barrier layer, and at least the well layer is a nitride semiconductor including indium.

With the above configuration, since a nitride semiconductor including indium has a growth rate and a composition that greatly varies with the plane direction, the transition wavelength of a portion of the active layer located above the projection/recess structure and its surroundings can be changed. By making positive use of this nature, the absorption edge wavelength in the light-outgoing end facet-adjacent region can be shortened. As a result, a nitride semiconductor laser with high output and low cost can be implemented.

In the nitride semiconductor laser of the present invention, preferably, the indium content of the well layer right under the optical waveguide structure is smaller in the light-outgoing end facet-adjacent region than in the region other than the light-outgoing end facet-adjacent region.

With the above configuration, the absorption edge wavelength in the light-outgoing end facet-adjacent region can be shortened. As a result, since absorption at the light-outgoing end facet can be reduced, a nitride semiconductor laser with high output and low cost can be implemented.

In the nitride semiconductor laser of the present invention, preferably, the thickness of the well layer right under the optical waveguide structure is smaller in the light-outgoing end facet-adjacent region than in the region other than the light-outgoing end facet-adjacent region.

With the above configuration, the absorption edge wavelength in the light-outgoing end facet-adjacent region can be shortened. As a result, since absorption at the light-outgoing end facet can be reduced, a nitride semiconductor laser with high output and low cost can be implemented.

In the nitride semiconductor laser of the present invention, preferably, the projection/recess structure is formed by direct working on the substrate.

With the above configuration, by direct working on the substrate before the crystal growth of the layered structure of the semiconductor laser, a structure capable of reducing optical damage at the end facet can be fabricated. Therefore, a high-output nitride semiconductor laser can be implemented without the necessity of increasing the number of steps and the cost.

In the nitride semiconductor laser of the present invention, preferably, the projection/recess structure exists only in the region other than the light-outgoing end facet-adjacent region, and the substrate is flat with no projections/recesses in the light-outgoing end facet-adjacent region.

With the above configuration, since the transition wavelength of the active layer right under the optical waveguide structure can be increased in the region other than the light-outgoing end facet-adjacent region. Therefore, the transition wavelength of the active layer in the light-outgoing end facet-adjacent region can be relatively shortened compared with that in the other region. That is, since absorption at the end facet can be reduced, a high-output nitride semiconductor laser can be easily implemented.

In the nitride semiconductor laser of the present invention, preferably, the optical waveguide structure is placed right above a recess of the projection/recess structure.

With the above configuration, since the growth rate is higher on a recess than on a projection, the dependence of the growth on the shape of the projection/recess structure can be further emphasized. As a result, a window structure can be formed where the transition wavelength of the active layer in light-outgoing end facet-adjacent region can be further shortened easily, and this can reduce absorption at the end facet. Thus, a high-output nitride semiconductor laser can be easily implemented.

In the nitride semiconductor laser of the present invention, preferably, the projection/recess structure is constructed of a dielectric film having an opening in which part of a surface of the substrate is exposed.

With the above configuration, the projection/recess structure can be formed by selectively growing a dielectric film on the substrate. In this case, since only the patterned dielectric film is placed on the substrate, no previous working on the substrate into a projection/recess shape by etching and the like is necessary, but the shape is controlled with only the conditions of the selective growth. Therefore, the shape of the projection/recess structure can be controlled precisely.

In the nitride semiconductor laser of the present invention, preferably, the width of the opening of the dielectric film is larger in the light-outgoing end facet-adjacent region than in the region other than the light-outgoing end facet-adjacent region, or no dielectric film exists in the light-outgoing end facet-adjacent region.

With the above configuration, the growth rate and mixed crystal composition of the active layer in the light-outgoing end facet-adjacent region can be greatly changed from those in the region other than the light-outgoing end facet-adjacent region. As a result, the transition wavelength in the light-outgoing end facet-adjacent region can be shortened, and this can reduce optical damage. Thus, a high-output nitride semiconductor laser can be implemented.

In the nitride semiconductor laser of the present invention, preferably, the semiconductor multilayer film is of a trapezoidal structure of which a section taken along a plane parallel to the end facets is trapezoidal and a top surface is flat.

With the above configuration, a portion of the active layer on the trapezoid of which the top surface is flat is a flat film. Therefore, good-quality crystal tends to be obtained, and also non-uniformity of current injection can be reduced. As a result, a high-output nitride semiconductor laser can be implemented.

In the nitride semiconductor laser of the present invention, preferably, the width of the top surface of the trapezoidal structure is larger in the light-outgoing end facet-adjacent region than in the region other than the light-outgoing end facet-adjacent region.

With the above configuration, the well layer thickness of the active layer can be reduced in the light-outgoing end facet-adjacent region due to the shape dependence of the growth rate. In other words, the absorption edge wavelength can be shortened, and thus absorption can be reduced, in the light-outgoing end facet-adjacent region. As a result, a nitride semiconductor laser with high output and low cost can be implemented.

In the nitride semiconductor laser of the present invention, preferably, sidewalls of the first semiconductor layer are constructed of (11-22) plane.

With the above configuration, the growth rate and composition of the flat portion and sidewalls of the projection/recess structure can be most modulated. In particular, in the case of InGaN, the growth rate on the (11-22) plane and the indium content are greatly reduced. Using this selective growth characteristic, the transition wavelength can be shortened in the light-outgoing end facet-adjacent region.

In the nitride semiconductor laser of the present invention, preferably, the projection/recess structure exists only in the light-outgoing end facet-adjacent region, and the substrate is flat with no projections/recesses in the region other than the light-outgoing end facet-adjacent region.

With the above configuration, since the transition wavelength of the active layer can be shortened in the light-outgoing end facet-adjacent region, the transition wavelength of the active layer in the light-outgoing end facet-adjacent region can be relatively shortened compared with that in the region other than the light-outgoing end facet-adjacent region. In other words, since absorption at the end facet can be reduced, a high-output nitride semiconductor laser can be easily implemented.

In the nitride semiconductor laser of the present invention, preferably, the projection/recess structure includes stripes, and the direction of the stripes is roughly parallel to a light propagation direction.

With the above configuration, the projection/recess structure has a roughly the same cross-sectional shape when cut along planes parallel to the light propagation direction. If the stripes are not parallel to the light propagation direction, light will be scattered, causing a serious adverse effect on the operation characteristics of the laser. With the above configuration, however, light is prevented from scattering loss. Thus, a nitride semiconductor laser with high output and low cost can be implemented.

In the nitride semiconductor laser of the present invention, preferably, the projection/recess structure includes stripes, and the direction of the stripes is roughly perpendicular to a light propagation direction.

With the above configuration, the absorption edge wavelength of the active layer in the light-outgoing end facet-adjacent region can be shortened, and thus optical damage due to light absorption in the light-outgoing end facet-adjacent region can be reduced. Moreover, since the light propagation direction and the projections/recesses are perpendicular to each other, light incurs scattering due to the shape. As a result, the electric field intensity at the light-outgoing end facet can be reduced. Thus, a nitride semiconductor laser with high output and low cost can be implemented.

In the nitride semiconductor laser of the present invention, preferably, a light confinement factor of the optical waveguide structure is smaller in the light-outgoing end facet-adjacent region than in the region other than the light-outgoing end facet-adjacent region.

With the above configuration, the light intensity distribution greatly expands in the light-outgoing end facet-adjacent region. As a result, the light intensity of the active layer in the light-outgoing end facet-adjacent region can be reduced, and this can reduce absorption in this region. Thus, a nitride semiconductor laser with high output and low cost can be implemented

In the nitride semiconductor laser of the present invention, preferably, the projection/recess structure exists under a region having no optical waveguide structure, and the substrate under a region having the optical waveguide structure is flat.

With the above configuration, the active layer is crystal-grown on a flat layer in a region responsible for optical gain. Also, the projection/recess structure for shortening the transition wavelength of the active layer in the light-outgoing end facet-adjacent region is separated from the region responsible for optical gain. Therefore, a window structure can be formed without degrading the crystal quality of the active layer. In other words, absorption in the light-outgoing end facet-adjacent region can be reduced while the crystal quality of the active layer is maintained. As a result, a nitride semiconductor laser with high output and low cost can be implemented.

In the nitride semiconductor laser of the present invention, preferably, a plane direction of a top surface of the semiconductor multilayer film matches with a plane direction of the principal surface of the substrate.

The above configuration has an advantage that the active layer is easily crystal-grown uniformly. Also, since the plane direction of the active layer matches with the substrate plane direction high in symmetry property, it is possible to make full use of the modulation of the growth rate and the composition depending on the shape of the projection/recess structure. Using this feature, the absorption edge wavelength in the light-outgoing end facet-adjacent region can be shortened remarkably, and this can reduce absorption. As a result, a nitride semiconductor laser with high output and low cost can be implemented.

In the nitride semiconductor laser of the present invention, preferably, the plane direction of the top surface of the semiconductor multilayer film in the light-outgoing end facet-adjacent region is inclined from the plane direction of the substrate toward a plane direction of the light-outgoing end facet.

With the above configuration, the growth rate and composition of the active layer in the light-outgoing end facet-adjacent region can be selectively modulated. For example, when InGaN is used for the well layer of the active layer, the In content, in particular, can be reduced. In other words, the absorption edge wavelength in the light-outgoing end facet-adjacent region can be shortened, and this can reduce absorption. As a result, a nitride semiconductor laser with high output and low cost can be implemented.

In the nitride semiconductor laser of the present invention, preferably, the plane direction of the top surface of the semiconductor multilayer film in the light-outgoing end facet-adjacent region is inclined by six degrees or less from the plane direction of the substrate toward the plane direction of the light-outgoing end facet.

With the above configuration, the active layer is inclined with respect to the principal surface of the substrate in the light-outgoing end facet-adjacent region. In this case, the growth rate of the active layer greatly changes in the light-outgoing end facet-adjacent region, and hence the absorption edge wavelength can be greatly shortened. Also, with the tilt of as small as six degrees or less, light having propagated through the portion of the active layer in the region other than the light-outgoing end facet-adjacent region continues propagating through the inclined active layer with hardly incurring unnecessary light loss. As a result, since absorption in the light-outgoing end facet-adjacent region can be reduced without incurring unnecessary light loss, a nitride semiconductor laser with high output and low cost can be implemented.

In the nitride semiconductor laser of the present invention, preferably, the principal surface of the substrate is (0001) plane.

With the above configuration, the thickness and mixed crystal composition of the active layer can be greatly modulated with the projection/recess structure. The reason is that InGaN generally used for the active layer is highly dependent on the plane direction. In particular, growth of InGaN on the (0001) plane is greatly different from that on any other plane direction. Using this feature, the transition wavelength of the active layer in the light-outgoing end facet-adjacent region can be shortened remarkably. As a result, reduction in optical damage and further high output can be achieved.

In the nitride semiconductor laser of the present invention, preferably, the principal surface of the substrate is (11-20) plane.

With the above configuration, the semiconductor laser can be fabricated on the (11-20) plane small in polarization. This provides an advantage that the oscillation wavelength is easy to design during crystal growth of a strained quantum well.

In the nitride semiconductor laser of the present invention, preferably, no electrode exists right above the light-outgoing end facet-adjacent region.

With the above configuration, no current is injected to the light-outgoing end facet. This can reduce leakage current due to the interface state or the surface level at the end facet, and thus a high-output nitride semiconductor laser can be implemented.

### ADVANTAGES OF THE INVENTION

According to the nitride semiconductor laser of the present invention, by making positive use of the high plane direction dependence of the crystal growth of nitride semiconductors, the transition wavelength of the active layer right under the optical waveguide structure in the light-outgoing end facet-adjacent region can be relatively shortened. As a result, light absorption in the light-outgoing end facet-adjacent region can be reduced and thus optical damage can be prevented, without the necessity of complicating the fabrication process. Thus, high output and low cost can be achieved.

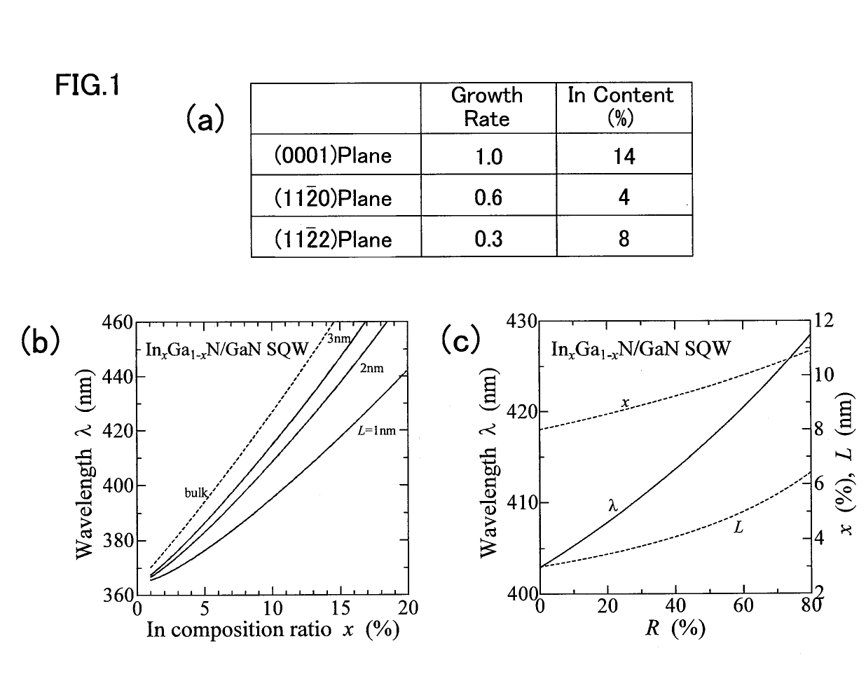

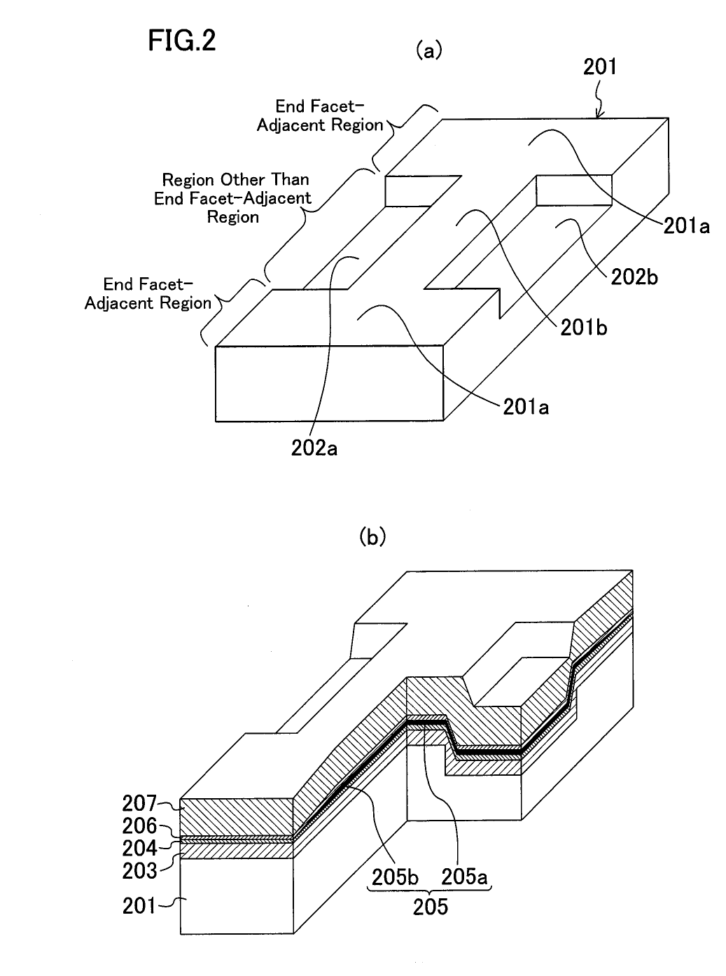

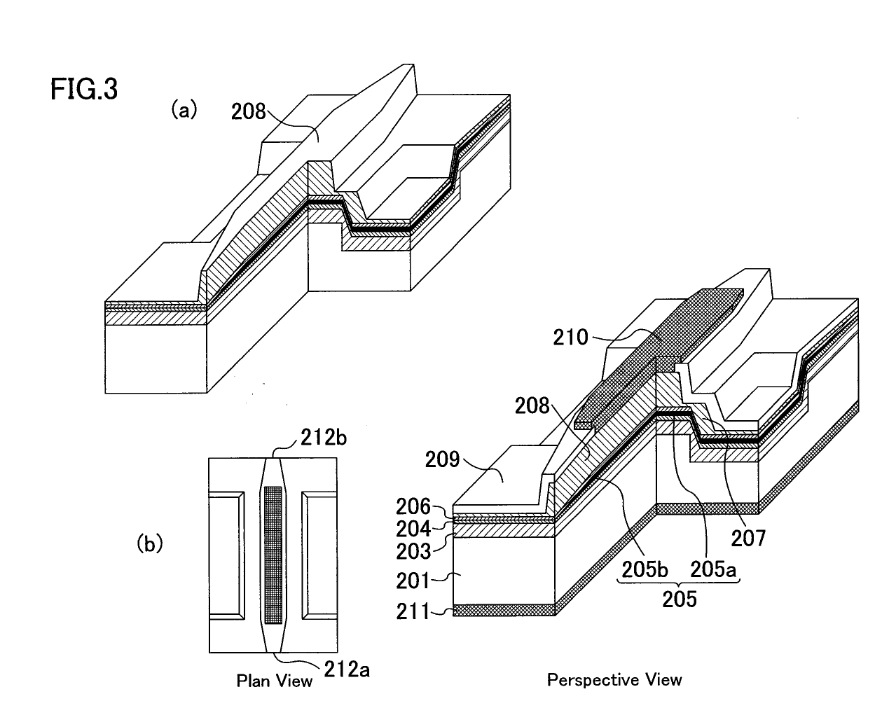

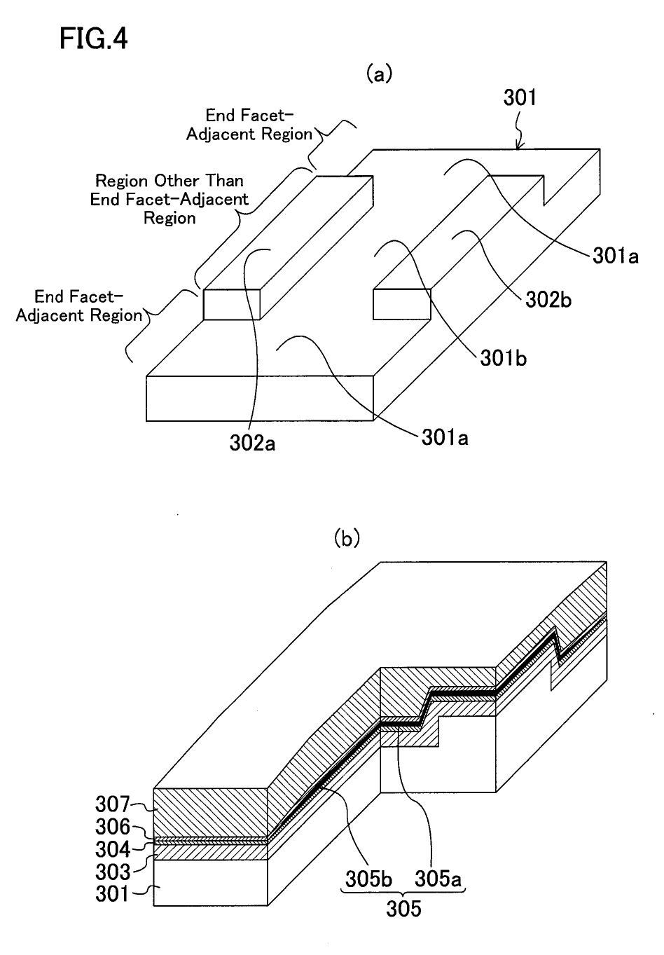

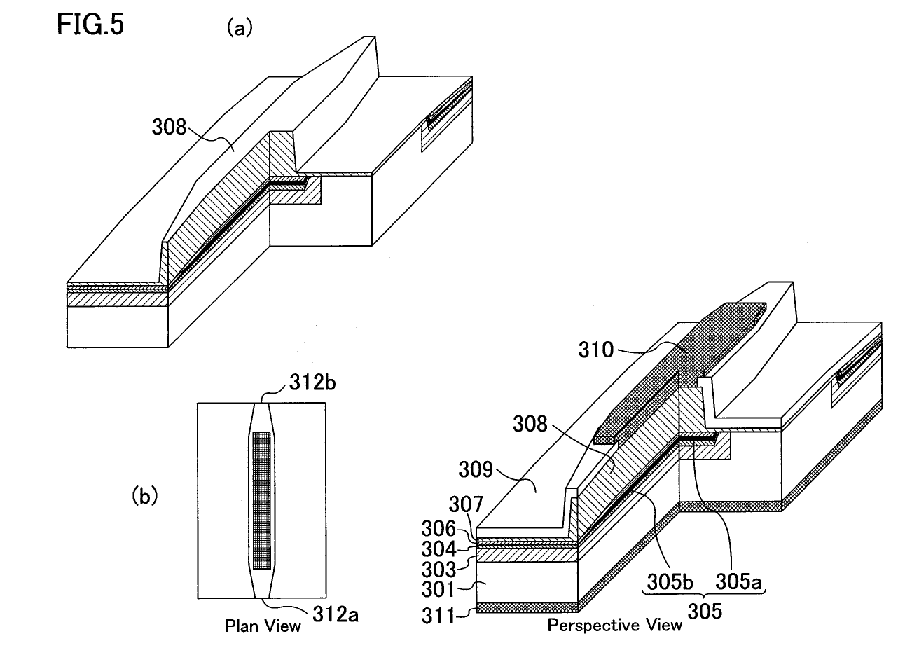

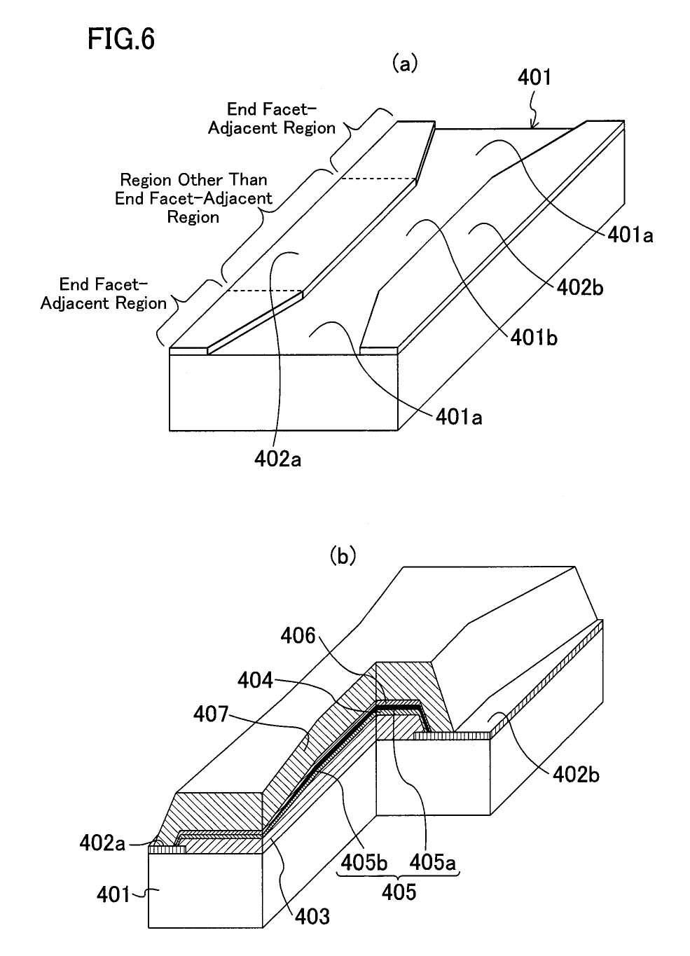

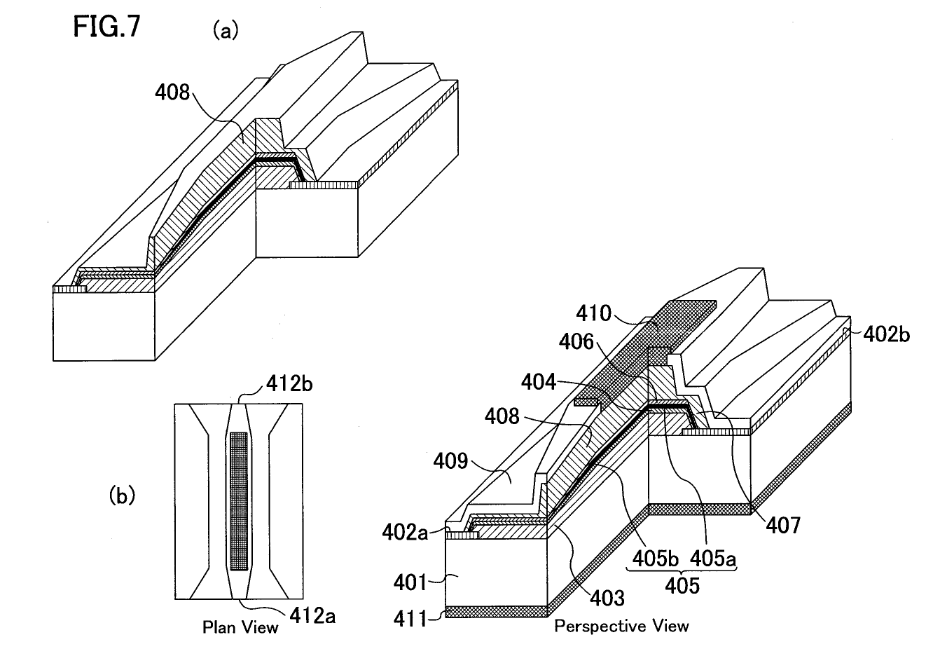

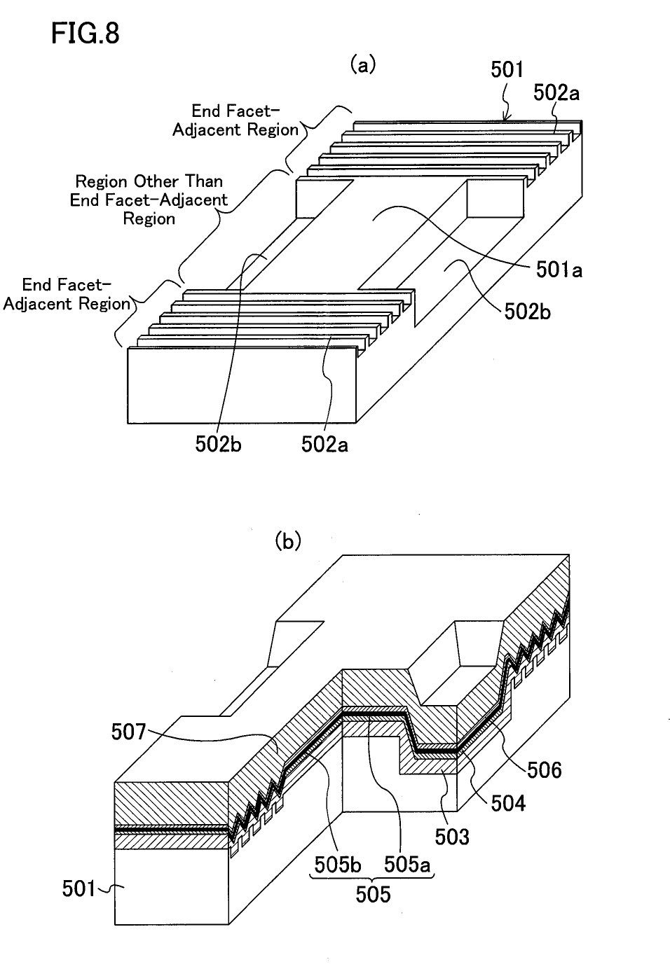

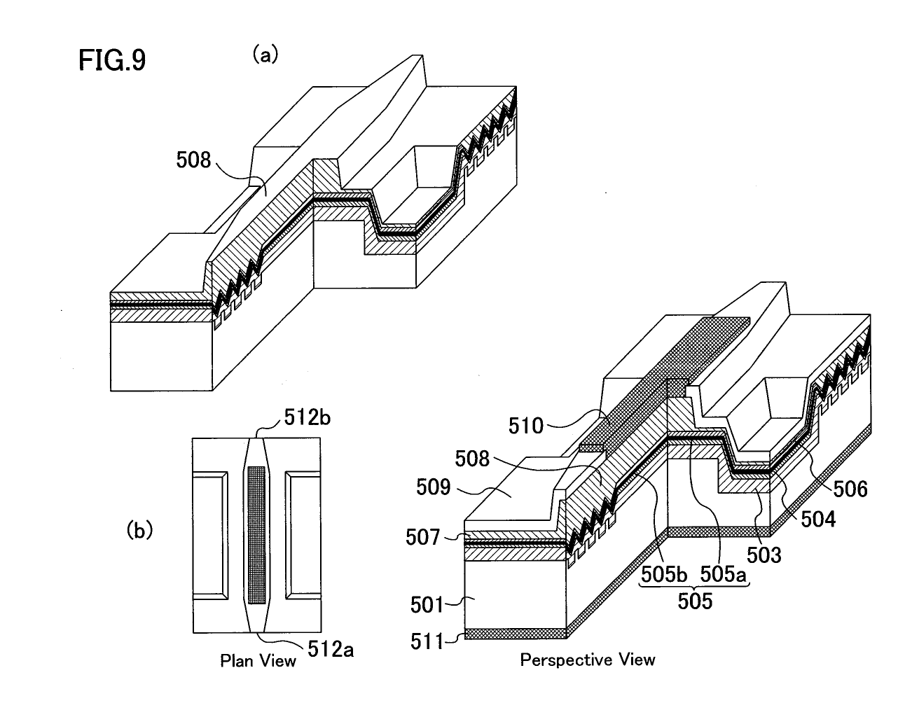

### BRIEF DESCRIPTION OF THE DRAWINGS

[FIG. 1] FIG. 1(a) is a view showing the growth rate and In content of InGaN in some plane directions, FIG. 1(b) is a view showing the relationship among the transition wavelength, the In content, and the well layer thickness in an InGaN/GaN multiple quantum well structure observed when the In content and the well layer thickness are changed, and FIG. 1(c) is a view showing the relationship between the in-plane aperture ratio and the transition wavelength of the InGaN/GaN multiple quantum well structure.

[FIG. 2] FIGS. 2(a) and 2(b) are views showing a fabrication method of a nitride semiconductor laser of the first embodiment of the present invention.

[FIG. 3] FIGS. 3(a) and 3(b) are views showing a configuration and fabrication method of the nitride semiconductor laser of the first embodiment.

[FIG. 4] FIGS. 4(a) and 4(b) are views showing a fabrication method of a nitride semiconductor laser of the second embodiment of the present invention.

[FIG. 5] FIGS. 5(a) and 5(b) are views showing a configuration and fabrication method of the nitride semiconductor laser of the second embodiment.

[FIG. 6] FIGS. 6(a) and 6(b) are views showing a fabrication method of a nitride semiconductor laser of the third embodiment of the present invention.

[FIG. 7] FIGS. 7(a) and 7(b) are views showing a configuration and fabrication method of the nitride semiconductor laser of the third embodiment.

[FIG. 8] FIGS. 8(a) and 8(b) are views showing a fabrication method of a nitride semiconductor laser of the fourth embodiment of the present invention.

[FIG. 9] FIGS. 9(a) and 9(b) are views showing a configuration and fabrication method of the nitride semiconductor laser of the fourth embodiment.

### DESCRIPTION OF REFERENCE CHARACTERS

201, 301, 401, 501 N-type GaN Substrate
201a, 301a Flat Portion
201b Beam
202a, 202b Recess
203, 303, 403, 503 N-type GaN Layer
204, 304, 404, 504 N-type InGaN Cladding Layer
205, 305, 405, 505 InGaN/InGaN Quantum Well Active Layer
205a, 205b Active Layer
206, 306, 406, 506 P-type InGaN Cladding Layer
207, 307, 407, 507 P-type GaN Layer
208, 308, 408, 508 Ridge Waveguide
209, 309, 409, 509 SiO₂ Film
210, 310, 410, 510 P-type Electrode
211, 311, 411, 511 N-type Electrode
212a, 202b End Facet
301b Recess
302a, 302b Projection
305a, 305b Active Layer
312a, 312b End Facet
401a Tapered Gap
401b Gap
402a, 402b Dielectric Mask
405a, 405b Active Layer
412a, 412b End Facet
417 nm Wavelength
501a Beam
502a Projection/Recess Portion
502b Recess
505a, 505b Active Layer
512a, 512b End Facet

### DESCRIPTION OF EMBODIMENTS

Best modes for carrying out the present invention will be described hereinafter with reference to the relevant drawings.

First, experimental facts obtained by the present inventors will be described.

FIG. 1(a) shows the growth rate and indium content of InGaN thin films grown on three plane directions. For the growth, trimethylgallium (TMG), trimethylindium (TMI), and ammonia (NH₃) were used as the precursors of gallium, indium, and nitrogen, respectively. The growth conditions are the same for all the plane directions, which include a growth temperature of 790° C., a precursor flow ratio of a V group to III groups (V/III ratio) of 6000, and a growth pressure of 300 Torr (4.0×10⁴ Pa). From FIG. 1(a), it is found that, under the above growth conditions, the indium content is highest in (0001) plane and indium is less taken in as the plane direction is inclined to (11-22) and then to (11-20). In particular, in comparison between the (0001) plane and (11-20) plane, it is found that there is an almost three-fold difference therebetween. The growth rate is highest in the (0001) plane, as in the case of the indium content, then in the (11-20) plane, and lowest in (11-22) plane. This is because the density of atomic species exposed is different among the plane directions. That is, while the (0001) plane is entirely covered with III-group atoms, the (11-20) plane is covered with III-group atoms and nitrogen atoms at a ratio of 1:1, and the (11-22) plane is covered with nitrogen atoms in an overwhelming proportion. Thus, the growth of nitride semiconductors greatly depends on the plane direction. As for (1-101) plane, which has nitrogen atoms in a large proportion like the (11-22) plane, the results are the same as those in the (11-22) plane.

Next, considered is the case of crystal growth of an InGaN/GaN single quantum well (SQW) structure on each of the above plane directions. Assuming that the thickness of an InGaN well layer is 3 nm on the (0001) plane, it will be about 2 nm and about 1 nm on the (11-20) plane and the (11-22) plane, respectively. In FIG. 1(b), the transition wavelength of the InGaN/GaN quantum well structure having each of these thicknesses is plotted with respect to the indium content on the x-axis. It is assumed in this plotting that the bowing constant of InGaN is 2.5 eV and an effect of polarization on the transition wavelength is neglected.

Based on the values of the growth film thickness and the indium content for each of the plane directions shown in FIG. 1(a), the transition wavelength is determined from the graph of FIG. 1(b): it is about 445 nm (corresponding to the thickness of 3 nm and the indium content of 14%) for the (0001) plane, about 383 nm (corresponding to the thickness of 2 nm and the indium content of 4%) for the (11-20) plane, and about 395 nm (corresponding to the thickness of 1 nm and the indium content of 8%) for the (11-22) plane. That is, although the growth conditions are the same, the transition wavelength can be greatly changed with the plane direction. The dependence of the growth on the plane direction is as large as about 50 nm in terms of the change amount of the transition wavelength.

When an active layer is grown on semiconductor layers that are adjacent to each other but are different in plane direction, the growth rate and the composition are further modulated, and as a result, the transition wavelength of the quantum well also changes greatly.

Consider a structure with an active layer grown on the (0001) plane and the (11-22) plane that are adjacent to each other. Since the growth rate on the (11-22) plane is about 30% of that on the (0001) plane as described above, redundant reactive atomic species on the (11-22) plane flow to the (0001) plane. As a result, the growth rate on the (0001) plane improves. Also, when InGaN is grown on the (0001) plane that is adjacent to the (11-22) plane, the indium content is high compared with a flat (0001) plane due to the difference in indium intake efficiency between the plane directions.

Assume that the ratio of the area occupied by the (11-22) plane to the entire exposed area is R. FIG. 1(c) shows the grown film thickness and the indium content on the (0001) plane observed when InGaN is grown on the surface having the area ratio R, together with the transition wavelength of the corresponding InGaN/GaN quantum well structure. Note that the grown film thickness and the indium content observed when InGaN is grown on the (0001) plane with no exposure of the (11-22) plane (corresponding to R=0) are 3 nm and 8%, respectively, and the transition wavelength at this time is about 403 nm. From FIG. 1(c), it is found that, as the area ratio R increases, both the indium content x and the grown film thickness L increase. This is because redundant part of the material flows from the (11-22) plane to the (0001) plane. With the increase of the indium content and the grown film thickness, the transition wavelength of the InGaN/GaN quantum well structure also increases. For example, when the area ratio R=50%, the transition wavelength is about 417 nm, indicating that the wavelength can be increased by as large as about 15 nm compared with the case that only the (0001) plane is exposed.

In other words, by forming projections/recesses on the substrate and performing crystal growth of an active layer of an InGaN/GaN quantum well structure on such a substrate, the transition wavelength of the active layer right under an optical waveguide structure can be relatively shortened in a light-outgoing end facet-adjacent region compared with that in a region other than the light-outgoing end facet-adjacent region. As a result, since absorption near the light-outgoing end facet can be reduced, a high-output, low-cost nitride semiconductor laser can be implemented.

Such projections/recesses may be formed (1) in the region other than the light-outgoing end facet-adjacent region or (2) in the light-outgoing end facet-adjacent region, or otherwise, (3) projections/recesses different in the cross-sectional shape taken along a plane parallel to the principal surface of the substrate are formed in the light-outgoing end facet-adjacent region and the region other than the light-outgoing end facet-adjacent region. In (1) above, by growing an active layer on semiconductor layers that are adjacent to each other but different in plane direction, it is possible to increase the transition wavelength of the active layer right under the optical waveguide structure in the region other than the light-outgoing end facet-adjacent region. In (2) above, it is possible to shorten the transition wavelength of the active layer right under the optical waveguide structure in the light-outgoing end facet-adjacent region. In (3) above, both the effects of (1) and (2) can be obtained. In any of the above three cases, the transition wavelength of the active layer right under the optical waveguide structure can be relatively shortened in the light-outgoing end facet-adjacent region than in the region other than the light-outgoing end facet-adjacent region.

### First Embodiment

FIGS. 2(a), 2(b), 3(a), and 3(b) are views showing a configuration and fabrication method of a nitride semiconductor laser of the first embodiment of the present invention. FIG. 3(b) shows a structure of the nitride semiconductor laser of the first embodiment in the forms of a perspective view and a plan view. For easy understanding, a portion including part of a beam 201b is cut away to show sections. FIG. 2(a) shows only a substrate and a projection/recess structure formed thereon, out of the structure of FIG. 3(b).

In the nitride semiconductor laser of this embodiment, as shown in FIG. 2(a), a projection/recess structure having recesses 202a and 202b is formed on an n-type GaN substrate 201 whose principal surface is the (0001) plane. The depth of the recesses 202a and 202b is 3 μm, and the width of the beam 201b extending between the recesses 202a and 202b is 3 μm. Regions near two end facets 212a and 212b including the light-outgoing end facet are defined as flat portions 201a. The length of the n-type GaN substrate along a side perpendicular to the end facets is 200 μm, and the range of each of the flat portions 201a is 30 μm from the corresponding end facet.

As shown in FIG. 2(b), a semiconductor multilayer film including an active layer is formed on the structure including the n-type GaN substrate 201 and the projection/recess structure. The semiconductor multilayer film is constructed of an n-type GaN layer 203 having a thickness of 500 nm, an n-type InGaN cladding layer (n-type cladding layer) 204 having a thickness of 50 nm, an InGaN/InGaN quantum well active layer 205, a p-type InGaN cladding layer (p-type cladding layer) 206 having a thickness of 50 nm, and a p-type GaN layer 207 having a thickness of 2 μm. The transition wavelength of an active layer 205b as a portion of the active layer 205 located above each of the flat portions 201a is short compared with that of an active layer 205a as a portion thereof located above the beam 201b. In a portion of the semiconductor multilayer film near the beam 201b, the (0001) plane of the n-type GaN layer 203, the n-type cladding layer 204, the active layer 205, and the p-type cladding layer 206 is surrounded with the (11-22) plane. The area occupation ratio of the (11-22) plane is about 50% from the dimensions of the structure. The active layer 205b formed above the flat (0001) plane portion 201a has a well layer having a thickness of 3 nm and an indium content of 8%, and thus the transition wavelength thereof is about 403 nm from FIG. 1(c). On the contrary, the transition wavelength of the active layer 205a above the beam 201b is about 417 nm from FIG. 1(c), which is long compared with that of the active layer 205b above the flat portion 201a.

As shown in FIGS. 3(a) and 3(b), a ridge waveguide 208 is formed from the p-type GaN layer 207. The waveguide width is 1.5 μm in the region above the beam 201b, designed to allow laser oscillation under the single-mode conditions. The waveguide width is gradually reduced from 1.5 μm in the region above each flat portion 201a, to as small as 0.5 μm at the narrowest position (corresponding with the light-outgoing end facet). Using such a structure, it is possible to weaken light confinement at the light-outgoing end facet.

An SiO₂ film 209 for insulation is formed over the ridge waveguide 208, and a p-type electrode 210 is formed on a portion of the ridge waveguide 208 exposed in an opening formed through the SiO₂ film 209 for current injection. The p-type electrode 210 is formed only right above the active layer 205a and is not formed above the active layer 205b. An n-type electrode 211 is formed on the back surface of the n-type GaN substrate 201.

The two end facets 212a and 212b including the light-outgoing end facet are formed perpendicularly to the plane of the flat portions 201a. Since the principal surface of the n-type GaN substrate 201 is the (0001) plane, the end facets are the (1-100) plane.

In the nitride semiconductor laser of this embodiment, the composition and thickness of the active layer vary along the waveguide direction (direction from one of the end facets 212a and 212b to the other). This is because, with the existence of the recesses 202a and 202b, the (0001) plane as the principal surface and a plane other than the (0001) plane are exposed close to each other in only the region on the n-type GaN substrate 201 other than the light-outgoing end facet-adjacent region. In other words, during the growth of the n-type GaN layer 203 on the n-type GaN substrate 201 having the recesses 202a and 202b, the (11-22) plane hard to grow is formed on the sidewalls of the recesses, and this causes modulation in the composition and thickness of the active layers 205a and 205b. Since a current is injected into the active layer 205a as shown in FIG. 3(b), laser oscillation occurs at a wavelength of 417 nm. Meanwhile, the active layer 205b, whose transition wavelength is 403 nm, hardly absorbs the wavelength of 417 nm, being nearly transparent to the laser light. If a large current is injected into this nitride semiconductor laser, such a current is to be injected only into the region of the active layer 205a, further increasing the 417-nm laser light output. Since the region of the active layer 205b is still transparent to the laser light, light absorption hardly occurs near the light-outgoing end facet. Therefore, with no abnormal heating due to light absorption occurring at the light-outgoing end facet, little or no element degradation due to optical damage arises even at the time of high output. In other words, the nitride semiconductor laser of this embodiment can perform stable high-output operation.

In this embodiment, if the range of the flat portion 201a is too small, light will scatter, decreasing the output. Conversely, if the proportion of the flat portion 201a in the size of the n-type GaN substrate 201 is too large, the region capable of obtaining optical gain will become too small. A preferred range of the flat portion 201a is up to 10 μm to 50 μm from the end facet when the length of the n-type GaN substrate 201 along a side perpendicular to the end facet is 200 μm. Within such a range, light scattering is small, and the region capable of obtaining optical gain can be sufficiently secured. More preferably, the length of the flat portion 201a in the direction perpendicular to the end facet is in the range of 10 μm to 30 μm. Within such a range, a wider optical-gain obtainable region can be secured. It is found from the length of the n-type GaN substrate 201 and the upper limit of the above range that the range of the flat portion 201a from the end facet within which sufficient optical gain can be secured is preferably 25% or less, more preferably 15% or less, of the length of the n-type GaN substrate 201.

The width of the ridge waveguide 208 is reduced in the region above the flat portion 201a. Since the effective refractive index right under the ridge waveguide 208 decreases in the region above the flat portion 201a, the light confinement factor decreases in this region to about 30% of that in the region having the beam 201b. This indicates that the electric field intensity of the active layer 205b is weak near the light-outgoing end facet and, as a result, light absorption of the active layer 205b decreases. This decreases optical damage at the time of high output and eventually promises stable high-output operation. In the meantime, the width of the ridge waveguide 208 is large in the region above the beam 201b. This permits sufficient light confinement into the active layer. In other words, this permits efficient light amplification and hence is advantageous in increasing the output of the nitride semiconductor laser.

Since the SiO₂ film 209 lies under the p-type electrode 210 in the region above the flat portion 210a, no current injection is made to the light-outgoing end facet-adjacent region. At a light-outgoing end facet, where the periodicity of crystal is broken, dangling bonds exist on the surface. Therefore, if a current is injected also to the light-outgoing end facet, a leakage current may occur via such dangling bonds, resulting in heating the light-outgoing end facet. In view of this, in the structure of this embodiment, the SiO₂ film 209 is placed above the flat portion 201a to avoid current injection, thereby to achieve high output.

As described above, in the first embodiment, stable operation and high reliability during high output of the nitride semiconductor laser is achieved by (1) modulating the transition wavelength of the active layer along the waveguide direction using the steps of the underlying layer, (2) reducing the light absorption density at and near the end facets with the tapered ridge waveguide, and (3) reducing the leakage current at the end facets with selection of the current injection region.

### Fabrication Method of the First Embodiment

FIGS. 2(a), 2(b), 3(a), and 3(b) show a fabrication method of the nitride semiconductor laser of the first embodiment of the present invention. Crystal growth is performed by metal organic chemical vapor deposition (MOCVD) using trimethylgallium (TMG), for example, as a gallium material, trimethylaluminum (TMA), for example, as an aluminum material, and trimethylindium (TMI), for example, as an indium material, for the III-group materials of the III-group nitride semiconductors shown in FIG. 2, and using ammonia (NH₃), for example, as a nitride material for the V-group material, doping Si using silane (SiH₄), for example, as an impurity material for the n-type semiconductor layers and Mg using cyclopentadienyl magnesium (CP2Mg), for example, as an impurity material for the p-type semiconductor layers.

First, as shown in FIG. 2(a), a projection/recess structure having the recesses 202a and 202b is formed on the n-type GaN substrate 201 having the (0001) plane as the principal surface. The projection/recess structure is formed in the following manner. An SiO₂ film is deposited as an dielectric mask by vapor deposition, and then a pattern is transferred to the SiO₂ film by light exposure and fluorocarbon reactive ion etching. Thereafter, the pattern is transferred from the SiO₂ film to the n-type GaN substrate 201 by chlorine-based dry etching, and then the SiO₂ film is entirely removed by hydrofluoric acid. The etched depth of the thus-formed recesses 202a and 202b is 3 μm, and the width of the beam 201b between the recesses 202a and 202b is 3 μm.

Thereafter, crystal growth is performed on the structure shown in FIG. 2(a) by MOCVD. The layered structure after the crystal growth is shown in FIG. 2(b), in which, for easy understanding, a portion including part of the recess 202b is cut away to show sections. The n-type GaN layer 203 having a thickness of 500 nm is first grown on the structure including the n-type GaN substrate 201 and the projection/recess structure.

The n-type GaN layer 203 is grown under the conditions of a growth temperature of 1000° C., a growth pressure of 200 Torr, a NH₃/TMG ratio of about 1000, and use of hydrogen as the carrier gas. The supply of the V-group material is comparatively small in this growth. At this time, the (11-22) plane is automatically exposed on the sidewalls of the recesses due to the plane direction dependence of the crystal growth rate. The reason for this is that, as discussed earlier, the (11-22) plane, which is constructed of nitrogen, becomes unstable under the conditions as described above, where the supply of the V-group material is comparatively small and hydrogen carrier gas having strong vapor etching property is used, resulting in decrease in growth rate.

On the n-type GaN layer 203, grown sequentially are the n-type InGaN cladding layer (n-type cladding layer) 204 having a thickness of 50 nm, the InGaN/InGaN quantum well active layer 205, the p-type InGaN cladding layer (p-type cladding layer) 206 having a thickness of 50 nm, and the p-type GaN layer 207 having a thickness of 2 μm. The InGaN/InGaN quantum well active layer 205 is grown under the conditions of a growth temperature of 790° C., a growth pressure of 200 Torr, a NH₃/TMG ratio of about 6000, and use of nitrogen as the main ingredient of the carrier gas, which are the same as the conditions described above with reference to FIG. 1.

FIG. 3(a) shows a structure with the ridge waveguide 208 formed on the structure of FIG. 2(b). Like the formation of the projection/recess structure, the chlorine-based dry etching technique is used for formation of the waveguide. That is, the ridge waveguide 208 is formed by etching the p-type GaN layer 207 into the shape as shown in FIG. 3(a).

The SiO₂ film 209 for isolation is formed over the ridge waveguide structure shown in FIG. 3(a), and the p-type electrode 210 is formed on a portion of the ridge waveguide 208 exposed in an opening formed through the SiO₂ film 209 for current injection by a liftoff technique. Note that the p-type electrode 210 is formed only right above the active layer 205a, not above the active layers 205b. The n-type electrode 211 is also formed on the back surface of the n-type GaN substrate 201. Finally, the two end facets 212a and 212b including the light-outgoing end facet are formed by a cleavage technique, to complete the nitride semiconductor laser of the present invention.

Although the active layers 205a and 205b are of the InGaN/InGaN quantum well structure in the first embodiment, aluminum may also be included in this structure. In this case, since it is possible to design the transition wavelength while allowing lattice matching with GaN, the degree of freedom of design of the nitride semiconductor laser can be dramatically improved.

Although the n-type electrode 211 is formed on the back surface of the n-type GaN substrate 201 in FIG. 3(b), it may be formed in the upper part of the element structure as far as it is electrically connected to the n-type GaN substrate 201. In this case, also, the effect of the present invention can be sufficiently exerted. Although the n-type substrate 201 is made of n-type GaN in the first embodiment, a substrate made of a species other than GaN, such as sapphire and silicon, can also be used.

Although the width of the ridge waveguide 208 is reduced in the region above the flat portion 201a in the first embodiment, the effect of the present invention will be sufficiently exerted even when the width is fixed along the waveguide direction. However, for achievement of further high output, it is effective to form the ridge waveguide 208 into the tapered shape.

In the first embodiment, portions of the n-type GaN layer 203, the n-type cladding layer 204, the active layer 205, and the p-type cladding layer 206 grown on the recesses 202a and 202b are described as having the (11-22) plane exposed. Alternatively, the (11-20) plane may be exposed as the sidewalls, and in this case, also, the effect of the present invention is sufficiently exerted. As specific growth conditions for exposing the (11-20) plane, recommended are a growth temperature of 1000° C., a growth pressure of 200 Torr, a NH₃/TMG ratio of about 10000, and use of nitrogen as the main ingredient of the carrier gas. In this case, since the (11-22) plane is stabilized due to the high NH₃/TMG ratio and is only slightly subjected to vapor etching with hydrogen carrier gas, it becomes easy for the (11-20) plane to emerge. Since the (11-20) plane is lower in indium intake efficiency than the (11-22) plane, the transition wavelength of the active layer 205a can be further shifted somewhat toward the long wavelength side compared with the case where the (11-22) plane is exposed. Assuming that the ratio of the area of the (11-20) plane to the surface area is the same as that in the case of the (11-22) plane, which is 50%, the transition wavelength of the active layer 205a can be further shifted somewhat toward the long wavelength side compared with the case of the (11-22) plane, and thus, relatively, light absorption near the light-outgoing end facet can be drastically reduced.

Although, the flat portion 201a is formed near each of the two end facets in this embodiment, it does not necessarily exist near each end facet, but can just exist near at least one end facet serving as the light-outgoing end facet.

### Second Embodiment

FIGS. 4(a), 4(b), 5(a), and 5(b) are views showing a configuration and fabrication method of a nitride semiconductor laser of the second embodiment of the present invention. FIG. 5(b) shows a structure of the nitride semiconductor laser of the second embodiment in the forms of a perspective view and a plan view. For easy understanding, a portion including part of a recess 301b is cut away to show sections. FIG. 4(a) shows only a substrate and a projection/recess structure formed thereon, out of the structure of FIG. 5(b).

In the nitride semiconductor laser of this embodiment, as shown in FIG. 4(a), a projection/recess structure having projections 302a and 302b is formed on an n-type GaN substrate 301 whose principal surface is the (0001) plane. The height of the projections 302a and 302b is 1 μm, and the width of a recess 301b extending between the projections 302a and 302b is 5 μm. Regions near two end facets 312a and 312b including the light-outgoing end facet are defined as flat portions 301a. The length of the n-type GaN substrate along a side perpendicular to the end facets is 200 μm, and the range of each of the flat portions 201a is 30 μm from the corresponding end facet.

As shown in FIG. 4(b), a semiconductor multilayer film including an active layer is formed on the structure including the n-type GaN substrate 301 and the projection/recess structure. The semiconductor multilayer film is constructed of an n-type GaN layer 303 having a thickness of 500 nm, an n-type InGaN cladding layer (n-type cladding layer) 304 having a thickness of 50 nm, an InGaN/InGaN quantum well active layer 305, a p-type InGaN cladding layer (p-type cladding layer) 306 having a thickness of 50 nm, and a p-type GaN layer 307 having a thickness of 2 μm. Note however that the n-type cladding layer 304, the InGaN/InGaN quantum well active layer 305, the p-type cladding layer 306, and the p-type GaN layer 307 do not exist on the projections 302a and 302b. The transition wavelength of an active layer 305b as a portion of the active layer 305 located above each of the flat portions 301a is short compared with that of an active layer 305a as a portion thereof located above the recess 301b. In a portion of the semiconductor multilayer film near the recess 301b, the (0001) plane of the n-type GaN layer 303, the n-type cladding layer 304, the active layer 305, and the p-type cladding layer 306 is surrounded with the (11-22) plane. The area occupation ratio of the (11-22) plane is about 50% from the dimensions of the structure. The active layer 305b formed above the flat (0001) plane portion 301a has a well layer having a thickness of 3 nm and an indium content of 8%, and thus the transition wavelength thereof is about 403 nm from FIG. 1(c). On the contrary, the transition wavelength of the active layer 305a above the recess 301b is about 417 nm, which is long compared with that above the flat portion.

As shown in FIGS. 5(a) and 5(b), a ridge waveguide 308 is formed from the p-type GaN layer 307. The waveguide width is 1.5 μm in the region above the recess 301b, designed to allow laser oscillation under the single-mode conditions. The waveguide width is gradually reduced from 1.5 μm in the region above each flat portion 301a, to as small as 0.5 μm at the narrowest position (corresponding with the light-outgoing end facet). Using such a structure, it is possible to weaken light confinement at the light-outgoing end facet. An SiO₂ film 309 for insulation is formed over the ridge waveguide 308, and a p-type electrode 310 is formed on a portion of the ridge waveguide 308 exposed in an opening formed through the SiO₂ film 309 for current injection. The p-type electrode 310 is formed only right above the active layer 305a and is not formed above the active layer 205b. An n-type electrode 311 is formed on the back surface of the n-type GaN substrate 301. The two end facets 312a and 312b including the light-outgoing end facet are formed perpendicularly to the plane of the flat portions 201a. Since the principal surface of the n-type GaN substrate 301 is the (0001) plane, the end facets are the (1-100) plane.

In the nitride semiconductor laser of this embodiment, the composition and thickness of the active layer vary along the waveguide direction. This is because, with the existence of the projections 302a and 302b, the (0001) plane as the principal surface and a plane other than the (0001) plane are exposed close to each other in only the region on the n-type GaN substrate 301 other than the light-outgoing end facet-adjacent region. In other words, during the growth of the n-type GaN layer 303 on the n-type GaN substrate 301 having the projections 302a and 302b, the (11-22) plane is formed on the sidewalls of the projections, and this causes modulation in the composition and thickness of the active layers 305a and 305b. Since a current is injected into the active layer 305a as shown in FIG. 5(b), laser oscillation occurs at a wavelength of 417 nm. Meanwhile, the active layer 305b, whose transition wavelength is 403 nm, hardly absorbs the wavelength of 417 nm, being nearly transparent to the laser light. If a large current is injected into this nitride semiconductor laser, such a current is to be injected only into the region of the active layer 305a, further increasing the 417-nm laser light output. Since the region of the active layer 305b is still transparent to the laser light, light absorption hardly occurs at the light-outgoing end facet. Therefore, with no abnormal heating due to light absorption occurring at the light-outgoing end facet, no element degradation due to optical damage arises even at the time of high output. In other words, the nitride semiconductor laser of this embodiment can perform stable high-output operation.

Also, in this embodiment, the n-type cladding layer 304, the InGaN/InGaN quantum well active layer 305, the p-type cladding layer 306, and the p-type GaN layer 307 do not exist on the projections 302a and 302b. Therefore, with the entire portion of the active layer that may cause absorption in the neighborhood of the recess 301b having been removed, unnecessary absorption loss can be advantageously avoided. Thus, high light-output operation can be performed with a further low current.

In this embodiment, if the range of the flat portion 301a is too small, light will scatter, decreasing the output. Conversely, if the proportion of the flat portion 301a in the size of the n-type GaN substrate 301 is too large, the region capable of obtaining optical gain will become too small. Therefore, a preferred range of the flat portion 301a is up to 10 μm to 50 μm from the end facet when the length of the n-type GaN substrate 201 along a side perpendicular to the end facet is 200 μm. Within such a range, light scattering is small, and the region capable of obtaining optical gain can be sufficiently secured. More preferably, the range may be up to 10 μm to 30 μm. Within such a range, a wider optical-gain obtainable region can be secured. It is found from the length of the n-type GaN substrate 301 and the upper limit of the above range that the range of the flat portion 301a from the end facet within which sufficient optical gain can be secured is preferably 25% or less, more preferably 15% or less, of the length of the n-type GaN substrate 301.

### Fabrication Method of the Second Embodiment

FIGS. 4(a), 4(b), 5(a), and 5(b) show a fabrication method of the nitride semiconductor laser of the second embodiment of the present invention.

The MOCVD technique is used for implementing the nitride semiconductor laser of the second embodiment of the present invention. The materials used are the same as those described in the first embodiment.

First, as shown in FIG. 4(a), a projection/recess structure having the projections 302a and 302b are formed on the n-type GaN substrate 301 having the (0001) plane as the principal surface. The projection/recess structure is formed in the following manner. An SiO₂ film is deposited as an dielectric mask by vapor deposition, and then a pattern is transferred to the SiO₂ film by light exposure and fluorocarbon reactive ion etching. Thereafter, the pattern is transferred from the SiO₂ film to the n-type GaN substrate 301 by chlorine-based dry etching, and then the SiO₂ film is entirely removed by hydrofluoric acid. The height of the thus-formed projections 302a and 302b is 1 μm, and the width of the recess 301b between the projections 302a and 302b is 5 μm. The other flat portions are defined as the flat portions 301a.

Thereafter, crystal growth is performed on the structure shown in FIG. 4(a) by MOCVD. The layered structure after the crystal growth is shown in FIG. 4(b), in which, for easy understanding, a portion including part of the recess 301b is cut away to show sections. The n-type GaN layer 303 having a thickness of 500 nm is first grown on the projection/recess structure. The n-type GaN layer 303 is grown under the conditions of a growth temperature of 1000° C., a growth pressure of 200 Torr, a NH₃/TMG ratio of about 1000, and use of hydrogen as the main ingredient of the carrier gas. At this time, the (11-22) plane is exposed on the sidewalls of the projections. The reason for this is that, as discussed earlier, the (11-22) plane, which is constructed of nitrogen, becomes unstable under the conditions as described above, where the supply of the V-group material is comparatively small and hydrogen carrier gas having strong vapor etching property is used, resulting in decrease in growth rate. Since the n-type GaN layer 303 is grown also on the sidewalls of the projections 302a and 302b laterally, the width of the recess 301b is reduced to as small as about 2 μm.

On the n-type GaN layer 303, grown sequentially are the n-type cladding layer 304 having a thickness of 50 nm, the InGaN/InGaN quantum well active layer 305, the p-type cladding layer 306 having a thickness of 50 nm, and the p-type GaN layer 307 having a thickness of 2 μm. The InGaN/InGaN quantum well active layer 305 is grown under the conditions of a growth temperature of 790° C., a growth pressure of 200 Torr, a NH₃/TMG ratio of about 6000, and use of nitrogen as the main ingredient of the carrier gas, which are the same as the conditions described above with reference to FIG. 1. In the crystal growth of the p-type GaN layer 307 under the above growth conditions, the growth rate is higher laterally than longitudinally. Therefore, the surface is flattened as shown in FIG. 4(b) burying the projections.

FIG. 5(a) shows a structure with the ridge waveguide 308 formed on the structure of FIG. 4(b). Like the formation of the projection/recess structure, the chlorine-based dry etching technique is used for formation of the waveguide. That is, the ridge waveguide 308 is formed by etching the p-type GaN layer 307 into the shape as shown in FIG. 5(a). Since portions of the p-type GaN layer 307 above the projections are thin compared with a portion thereof above the recess 301b, portions of the active layer above the projections are also etched away during the formation of the ridge waveguide 308 by etching.

The SiO₂ film 309 for isolation is formed over the ridge waveguide structure shown in FIG. 5(a), and the p-type electrode 310 is formed on a portion of the ridge waveguide 308 exposed in an opening formed through the SiO₂ film 309 for current injection by a liftoff technique. Note that the p-type electrode 310 is formed only right above the active layer 305a, not above the active layers 305b. The n-type electrode 311 is also formed on the back surface of the n-type GaN substrate 301. Finally, the two end facets 312a and 312b including the light-outgoing end facet are formed by a cleavage technique, to complete the nitride semiconductor laser of the present invention.

In the fabrication method of this embodiment, the portions of the InGaN/InGaN quantum well active layer 305 located above the projections 302a and 302b are also removed by dry etching during the formation of the ridge waveguide 308 shown in FIG. 5(a). This is because, under the above growth conditions, the recess is filled with the p-type GaN layer 307 flattening the surface during the growth of the p-type GaN layer 307, and thus the portions of the p-type GaN layer 307 located above the projections are relatively thin. Therefore, since the entire of the portion of the active layer that may cause absorption in the neighborhood of the recess 301b has been removed, unnecessary absorption loss can be advantageously avoided. Thus, high light-output operation can be performed with a further low current.

Also in this embodiment, the width of the recess 301b can be controlled by changing the growth conditions of the n-type GaN layer 303. When the lateral/longitudinal ratio of the growth rate is large, the valley formed by etching can be narrowed by the growth of the n-type GaN layer 303. In other words, the following merit can be obtained: ultra-fine etching is unnecessary, and moreover the etching can be simplified, for formation of the valley.

Although the active layers 305a and 305b are of the InGaN/InGaN quantum well structure in the second embodiment, aluminum may also be included in this structure. In this case, since it is possible to design the transition wavelength while allowing lattice matching with GaN, the degree of freedom of design of the nitride semiconductor laser can be dramatically improved.

Although the n-type electrode 311 is formed on the back surface of the n-type GaN substrate 301 in FIG. 5(b), it may be formed in the upper part of the element structure as far as it is electrically connected to the n-type GaN substrate 301. In this case, also, the effect of the present invention can be sufficiently exerted. Although the n-type substrate 301 is made of n-type GaN in the second embodiment, a substrate made of a species other than GaN, such as sapphire and silicon, can also be used.

Although the width of the ridge waveguide 308 is reduced in the region above each flat portion 301a in the second embodiment, the effect of the present invention will be sufficiently exerted even when the width is fixed along the waveguide direction. However, for achievement of further high output, it is effective to taper the width of the ridge waveguide 308.

In the second embodiment, portions of the n-type GaN layer 303, the n-type cladding layer 304, the active layer 305, and the p-type cladding layer 306 grown on the projections 302a and 302b are described are described as having the (11-22) plane exposed. Alternatively, the (11-20) plane may be exposed as the sidewalls, and in this case, also, the effect of the present invention is sufficiently exerted. As specific growth conditions for exposing the (11-20) plane, recommended are a growth temperature of 1000° C., a growth pressure of 200 Ton, a NH₃/TMG ratio of about 10000, and use of nitrogen as the main ingredient of the carrier gas. In this case, since the (11-22) plane is stabilized due to the high NH₃/TMG ratio and is only slightly subjected to vapor etching with hydrogen carrier gas, it becomes easy for the (11-20) plane to emerge. Since the (11-20) plane is lower in indium intake efficiency than the (11-22) plane, the transition wavelength of the active layer 305a can be further shifted somewhat toward the long wavelength side compared with the case where the (11-22) plane is exposed. Assuming that the ratio of the area of the (11-20) plane to the surface area is the same as that in the case of the (11-22) plane, which is 50%, the transition wavelength of the active layer 305a can be further shifted somewhat toward the long wavelength side compared with the case of the (11-22) plane, and thus, relatively, light absorption near the light-outgoing end facet can be drastically reduced.

Although, the flat portion 301a exists near each of the two end facets in this embodiment, it does not necessarily exist near each end facet, but may just exist near at least one end facet serving as the light-outgoing end facet.

### Third Embodiment

FIGS. 6(a), 6(b), 7(a), and 7(b) are views showing a configuration and fabrication method of a nitride semiconductor laser of the third embodiment of the present invention. FIG. 7(b) shows a structure of the nitride semiconductor laser of the third embodiment in the forms of a perspective view and a plan view. For easy understanding, a portion including part of a gap 401b is cut away to show sections. FIG. 6(a) shows only a substrate and a projection/recess structure formed thereon, out of the structure of FIG. 7(b).

As shown in FIG. 6(a), dielectric masks 402a and 402b of SiO₂ are formed on an n-type GaN substrate 401 whose principal surface is the (0001) plane. The dielectric masks 402a and 402b are formed of a SiO₂ film having a thickness of 200 nm. A gap 401b as a narrow portion of an opening separating the dielectric masks 402a and 402b from each other has a width of 5 μm. The opening between the dielectric masks 402a and 402b is gradually widened from the gap 401b toward two end facets 412a and 412b (see FIG. 7(b)) including the light-outgoing end facet, to form tapered gaps 401a. The width of the tapered gaps 401a is 30 μm at the ends having the end facets 412a and 412b. The length of the n-type GaN substrate 401 along a side perpendicular to the end facets is 200 μm, and the position at which the width of the gap 401b starts increasing is 30 μm from each end facet.

As shown in FIG. 6(b), a semiconductor multilayer film including an active layer is formed on the structure including the n-type GaN substrate 401 and the dielectric masks 402a and 402b. The semiconductor multilayer film is constructed of an n-type GaN layer 403 having a thickness of 500 nm, an n-type InGaN cladding layer (n-type cladding layer) 404 having a thickness of 50 nm, an InGaN/InGaN quantum well active layer 405, a p-type InGaN cladding layer (p-type cladding layer) 406 having a thickness of 50 nm, and a p-type GaN layer 407 having a thickness of 2 μm. The section of the n-type GaN layer 403, the n-type cladding layer 404, the InGaN/InGaN quantum well active layer 405, the p-type cladding layer 406, and the p-type GaN layer 407 taken along a plane parallel to the light-outgoing end facet has a trapezoidal shape. Also, an active layer 405b as a portion of the active layer 405 located above each of the tapered gaps 401a is slightly inclined from the (0001) plane toward the plane of the light-outgoing end facet. In a portion of the semiconductor multilayer film near the gap 401b, the (0001) plane of the n-type GaN layer 403, the n-type cladding layer 404, the active layer 405, and the p-type cladding layer 406 is surrounded with the (11-22) plane. While the transition wavelength of the active layer 405b above the tapered gap 401a is 403 nm, the transition wavelength of an active layer 405a as a portion of the active layer 405 located above the narrow gap 401b is about 417 nm, indicating that the transition wavelength of the active layer 405b is short compared with that of the active layer 405a.

As shown in FIGS. 7(a) and 7(b), a ridge waveguide 408 is formed from the p-type GaN layer 407. The waveguide width is 1.5 μm in the region above the narrow gap 401b, designed to allow laser oscillation under the single-mode conditions. The waveguide width is gradually reduced from 1.5 μm in the region above each tapered gap 401a to as small as 0.5 μm at the narrowest position (corresponding with the light-outgoing end facet). Using such a structure, it is possible to weaken light confinement at the light-outgoing end facet.

An SiO₂ film 409 for insulation is formed over the ridge waveguide 408, and a p-type electrode 410 is formed on a portion of the ridge waveguide 408 exposed in an opening formed through the SiO₂ film 409 for current injection. The p-type electrode 410 is formed only right above the active layer 405a and is not formed above the active layer 405b. An n-type electrode 411 is formed on the back surface of the n-type GaN substrate 401. The two end facets 412a and 412b including the light-outgoing end facet are formed perpendicularly to the principal surface of the n-type GaN substrate 401.

In the nitride semiconductor laser of this embodiment, the composition and thickness of the active layer vary along the waveguide direction. This is because, with the existence of the dielectric masks 402a and 402b the opening between which changes in its width, the growth mode is modulated as described earlier. Since a current is injected into the active layer 405a as shown in FIG. 7(b), laser oscillation occurs at a wavelength of 417 nm. Meanwhile, the active layer 405b, whose transition wavelength is 403 nm, hardly absorbs the wavelength of 417 nm, being nearly transparent to the laser light. If a large current is injected into this nitride semiconductor laser, such a current is to be injected only into the region of the active layer 405a, further increasing the 417-nm laser light output. Since the region of the active layer 405b is still transparent to the laser light, light absorption hardly occurs at the light-outgoing end facet. Therefore, with no abnormal heating due to light absorption occurring at the light-outgoing end facet, little or no element degradation due to optical damage arises even at the time of high output. In other words, the nitride semiconductor laser of this embodiment can perform stable high-output operation.

In this embodiment, if the range of the tapered gap 401a is too small, light will scatter, decreasing the output. Conversely, if the proportion of the tapered gap 401a in the size of the n-type GaN substrate 401 is too large, the region capable of obtaining optical gain will become too small. A preferred range of the tapered gap 401a is up to 10 μm to 50 μm from the end facet when the length of the n-type GaN substrate 401 along a side perpendicular to the end facet is 200 μm. Within such a range, light scattering is small, and the region capable of obtaining optical gain can be sufficiently secured. More preferably, the range may be up to 10 μm to 30 μm. Within such a range, a wider optical-gain obtainable region can be secured. It is found from the length of the n-type GaN substrate 401 and the upper limit of the above range that the range of the tapered gap 401a from the end facet within which sufficient optical gain can be secured is preferably 25% or less, more preferably 15% or less, of the length of the n-type GaN substrate 401.

A merit of the third embodiment is that a high-output nitride semiconductor laser can be fabricated by only forming the dielectric masks 402a and 402b on the n-type GaN substrate 401 and performing selective growth, with little increase in cost.

Since the transition wavelength of the active layer 405b near the light-outgoing end facet is short, the refractive index of the active layer 405b is low compared with that of the active layer 405a. Also, with the vertical thickness of the active layer 405b being small, vertical light confinement is weak. Moreover, since the width of the ridge waveguide 408 is small at the light-outgoing end facet, transverse light confinement is also weak. As a result, the optical electric field intensity of the active layer is considerably low at the light-outgoing end facet, and thus optical damage can be made less likely to occur even during high light-output operation.

FIGS. 6(a), 6(b), 7(a), and 7(b) show a fabrication method of the nitride semiconductor laser of the third embodiment of the present invention.

The MOCVD technique is used for implementing the nitride semiconductor laser of the third embodiment of the present invention. The materials used are the same as those described in the first embodiment.

First, as shown in FIG. 6(a), dielectric masks 402a and 402b are formed on the n-type GaN substrate 401 having the (0001) plane as the principal surface. The dielectric masks 402a and 402b are formed in the following manner. An SiO₂ film having a thickness of 200 nm is deposited by vapor deposition, and then a pattern is transferred to the SiO₂ film by light exposure and fluorocarbon reactive ion etching. The width of the gap 401b as a narrow portion of the opening between the thus-formed dielectric masks 402a and 402b is 5 μm. The opening between the dielectric masks 402a and 402b is gradually widened from the gap 401b toward the two end facets 412a and 412b including the light-outgoing end facet, to form the tapered gaps 401a. The width of the tapered gaps 401a is 30 μm at the ends having the end facets 412a and 412b.

Thereafter, crystal growth is performed on the structure shown in FIG. 6(a) by MOCVD. The layered structure after the crystal growth is shown in FIG. 6(b), in which, for easy understanding, a portion including part of the gap 401b is cut away to show sections. The n-type GaN layer 403 having a thickness of 500 nm is first grown on the structure shown in FIG. 6(a). The n-type GaN layer 403 is grown under the conditions of a growth temperature of 1000° C., a growth pressure of 200 Torr, a NH₃/TMG ratio of about 1000, and use of hydrogen as the main ingredient of the carrier gas. At this time, the n-type GaN layer 403 is grown on the tapered gaps 401a and the gap 401b into a trapezoidal cross-sectional shape, and as a result of the crystal growth, the (11-22) plane is exposed on the sidewalls of the trapezoid. The reason is that, under the above growth conditions where the NH₃/TMG ratio is low and vapor etching with hydrogen is promoted, the unstable (11-22) plane tends to be exposed. As a result of the growth of the n-type GaN layer 403, in which the growth rate is lower laterally than longitudinally, the width of the tapered gaps 401a and the gap 401b little increases.

On the n-type GaN layer 403, grown sequentially are the n-type cladding layer 404 having a thickness of 50 nm, the InGaN/InGaN quantum well active layer 405, the p-type cladding layer 406 having a thickness of 50 nm, and the p-type GaN layer 407 having a thickness of 2 μm. The InGaN/InGaN quantum well active layer 405 is grown under the conditions of a growth temperature of 790° C., a growth pressure of 200 Torr, a NH₃/TMG ratio of about 6000, and use of nitrogen as the main ingredient of the carrier gas, which are the same as the conditions described above with reference to FIG. 1. As discussed earlier with reference to FIG. 1, the transition wavelength of the active layer 405b above the tapered gap 401a having a large width is short compared with the transition wavelength of the active layer 405a above the gap 401b having a small width.

The above fact is due to the following three reasons. The first reason is that the growth rate changes with the opening width of the dielectric mask. Since the active layer 405b above the wide tapered gap 401a is low in its growth rate, the transition wavelength is shortened. The second reason is the plane direction dependence of InGaN. That is, in the active layer 405a above the narrow gap 401b, the exposed area of the (11-22) plane that is low in InGaN growth rate and low in In content is relatively high compared with the exposed area of the (0001) plane. Therefore, the InGaN growth rate and the In content of the active layer 405a are comparatively high, and as a result, the transition wavelength thereof is increased. The third reason is the gradual change of the width of the tapered gap 401a. Due to the dependence of the growth rate on the mask opening width, the growth rate is higher as the position on the tapered gap 401a is closer to the narrow gap 401b and lower as it is closer to the wide opening end. As a result, the crystal-grown n-type GaN layer 403 has a minute tilt on its surface, inclined slightly from the (0001) plane. The indium intake efficiency of InGaN decreases as the plane direction is inclined from the (0001) plane. Thus, the transition wavelength of the active layer 405b above the tapered gap 401a shortened. Due to the three reasons described above, the wavelength of the active layer 405b above the tapered gap 401a can be shortened.

The tilt angle of the active layer 405b above the tapered gap 401a must be within six degrees from the (0001) plane. This is necessary for efficient propagation of laser light from the active layer 405a to the active layer 405b. If the tilt angle exceeds six degrees, the loss due to an abrupt curve of the waveguide will increase significantly, damaging the high light-output operation. For this reason, the width of the tapered gap 401a must be mild with respect to the light propagation direction. For example, for a length of 20 μm, the width must be continuously widened from 5 μm to 30 μm.

FIG. 7(a) shows a structure with the ridge waveguide 408 formed on the structure of FIG. 6(b). For formation of the waveguide, the chlorine-based dry etching technique is used. That is, the ridge waveguide 408 is formed by etching the p-type GaN layer 407 into the shape as shown in FIG. 7(a).

The SiO₂ film 409 for isolation is formed over the ridge waveguide structure shown in FIG. 7(a), and the p-type electrode 410 is formed on a portion of the ridge waveguide 408 exposed in an opening formed through the SiO₂ film 409 for current injection by a liftoff technique. Note that the p-type electrode 410 is formed only right above the active layer 405a, not above the active layer 405b. The n-type electrode 411 is also formed on the back surface of the n-type GaN substrate 401. Finally, the two end facets 412a and 412b including the light-outgoing end facet are formed by a cleavage technique, to complete the nitride semiconductor laser of the present invention.

Although the active layers 405a and 405b are of the InGaN/InGaN quantum well structure in the third embodiment, aluminum may also be included in this structure. In this case, since it is possible to design the transition wavelength while allowing lattice matching with GaN, the degree of freedom of design of the nitride semiconductor laser can be dramatically improved.

Although the n-type electrode 411 is formed on the back surface of the n-type GaN substrate 401 in FIG. 7(b), it may be formed in the upper part of the element structure as far as it is electrically connected to the n-type GaN substrate 401. In this case, also, the effect of the present invention can be sufficiently exerted. Although the n-type substrate 401 is made of n-type GaN in the third embodiment, a substrate made of a species other than GaN, such as sapphire and silicon, can also be used.

Although the width of the ridge waveguide 408 is reduced in the region above each tapered gap 401a in the third embodiment, the effect of the present invention will be sufficiently exerted even when the width is fixed along the waveguide direction. However, for achievement of further high output, it is effective to taper the width of the ridge waveguide 408.

In the third embodiment, although the dielectric masks 402a and 402b are described as existing also near the end facets, they may not exist near the end facets. In this case, since the active layer is to be grown on the flat surface in the end portion, the growth mode can be most distinguished from that of the active layer 405b above the gap 401b.

Although the n-type GaN layer 403 is described as having the (11-22) plane exposed on the sidewalls, the (11-20) plane may be exposed as the sidewalls. In this case, also, the effect of the present invention is sufficiently exerted. As specific growth conditions for exposing the (11-20) plane, recommended are a growth temperature of 1000° C., a growth pressure of 200 Torr, a NH₃/TMG ratio of about 10000, and use of nitrogen as the main ingredient of the carrier gas. In this case, since the nitrogen-polar (11-22) plane is stabilized and is little subjected to vapor etching with hydrogen, growth of the plane (11-22) is promoted, and thus it becomes easy for the (11-20) plane to emerge. In this case, also, it is possible to differentiate the transition wavelength between the active layers 405a and 405b.

Although, the tapered gap 401a exists near each of the two end facets in this embodiment, it does not necessarily exist near each end facet, but can just exist near at least one end facet serving as the light-outgoing end facet.

### Fourth Embodiment

FIGS. 8(a), 8(b), 9(a), and 9(b) are views showing a configuration and fabrication method of a nitride semiconductor laser of the fourth embodiment of the present invention. FIG. 9(b) shows a structure of the nitride semiconductor laser of this embodiment in the forms of a perspective view and a plan view. For easy understanding, a portion including the center of the element is cut away to show sections. FIG. 8(a) shows only a substrate and a projection/recess structure formed thereon, out of the structure of FIG. 9(b).

In this embodiment, as shown in FIG. 8(a), a projection/recess structure having projection/recess portions 502a and recesses 502b is formed on an n-type GaN substrate 501 whose principal surface is the (0001) plane. The projection/recess portions 502a are formed in parallel with the <11-20> direction. The depth of recesses of the projection/recess portions 502a is 0.05 μm, the depth of the recesses 502b is 3 μm, and the width of a beam 501a extending between the recesses 502b is 3 μm. The projection/recess portions 502a have rectangular projections and recesses. The projection/recess portions 502a are formed near two end facets 512a and 512b including the light-outgoing end facet. The length of the n-type GaN substrate 501 along a side perpendicular to the end facets is 200 μm, and the range of each of the projection/recess portions 502a is 30 μm from the corresponding end facet.

As shown in FIG. 8(b), a semiconductor multilayer film including an active layer is formed on the structure including the n-type GaN substrate 501 and the projection/recess structure. The semiconductor multilayer film is constructed of an n-type GaN layer 503 having a thickness of 500 nm, an n-type InGaN cladding layer (n-type cladding layer) 504 having a thickness of 50 nm, an InGaN/InGaN quantum well active layer 505, a p-type InGaN cladding layer (p-type cladding layer) 506 having a thickness of 50 nm, and a p-type GaN layer 507 having a thickness of 2 μm. The transition wavelength of an active layer 505b as a portion of the active layer 505 located above each of the projection/recess portions 502a is short compared with that of an active layer 505a as a portion thereof located above the beam 501a. In a portion of the semiconductor multilayer film near the beam 501a, the (0001) plane of the n-type GaN layer 503, the n-type cladding layer 504, the active layer 505a, and the p-type cladding layer 506 is surrounded with the (11-22) plane. The area occupation ratio of the (11-22) plane is about 50% from the dimensions of the structure. With this state that is same as that of the active layer 205a above the beam 201b in the first embodiment, the transition wavelength of the active layer 505a is about 417 nm from FIG. 1(c). In addition, since the portions of the n-type GaN layer 503, the n-type cladding layer 504, the active layer 505, and the p-type cladding layer 506 located above the projection/recess portions 502 include the (1-101) plane, the InGaN film thickness and In content of the active layer 505b are small compared with those of an active layer formed on the flat (0001) plane. As a result, the transition wavelength of the active layer 505b is short compared with an active layer formed on the flat (0001) plane. Since the well layer of the active layer formed on the flat (0001) plane has a thickness of 3 μm and an indium content of 8% in the first embodiment, the thickness and the indium content of the well layer of the active layer 505b on the (1-101) plane are 1 nm and about 5%, respectively, from the relationship shown in FIG. 1(a). Assume in this case that the growth dependence of the nitride semiconductor layer on the (1-101) plane is roughly the same as that on the (11-22) plane. From the well layer thickness, the indium content, and the graph of FIG. 1(c), the transition wavelength of the active layer 505b is 375 nm.

A ridge waveguide 508 is formed from the p-type GaN layer 507. The waveguide width is 1.5 μm in the region above the beam 501a, designed to allow laser oscillation under the single-mode conditions. The waveguide width is gradually reduced from 1.5 μm in the region above each projection/recess portion 502a to as small as 0.5 μm at the narrowest position (corresponding with the light-outgoing end facet). Using such a structure, it is possible to weaken light confinement at the light-outgoing end facet.

An SiO₂ film 509 for insulation is formed over the ridge waveguide 508, and a p-type electrode 510 is formed on a portion of the ridge waveguide 508 exposed in an opening formed through the SiO₂ film 509 for current injection. The p-type electrode 510 is formed only right above the active layer 505a and is not formed above the active layer 505b. An n-type electrode 511 is formed on the back surface of the n-type GaN substrate 501. The two end facets 512a and 512b including the light-outgoing end facet are formed perpendicularly to the principal surface of the n-type GaN substrate 501. Since the principal surface of the n-type GaN substrate 501 is the (0001) plane, the end facets are the (1-100) plane.

In the nitride semiconductor laser of this embodiment, the composition and thickness of the active layer vary along the waveguide direction. This is because the (0001) plane as the principal surface and a plane other than the (0001) plane are exposed close to each other in the region on the n-type GaN substrate 301 other than the light-outgoing end facet-adjacent region, and the (1-101) plane is exposed in the region on the n-type GaN substrate near the light-outgoing end facet. In other words, during the growth of the n-type GaN layer 503 on the n-type GaN substrate 501 having the recesses 502b, the (11-22) plane is formed on the sidewalls of the recesses 502b. Also, during this growth of the n-type GaN layer 503, the (1-101) plane is formed on the projection/recess portion 502a. This causes modulation in the composition and thickness of the active layers 505a and 505b. Since a current is injected only into the active layer 505a as shown in FIG. 9(b), laser oscillation occurs at a wavelength of 417 nm. Meanwhile, the active layer 505b, whose transition wavelength is 375 nm, hardly absorbs the wavelength of 417 nm, being nearly transparent to the laser light. If a large current is injected into this nitride semiconductor laser, such a current is to be injected only into the region of the active layer 505a, further increasing the 417-nm laser light output. Since the region of the active layer 505b is still transparent to the laser light, light absorption hardly occurs near the light-outgoing end facet. Therefore, with no abnormal heating due to light absorption occurring at the light-outgoing end facet, no element degradation due to optical damage arises even at the time of high output. In other words, the nitride semiconductor laser of this embodiment can perform stable high-output operation.

In this embodiment, if the range of the projection/recess portion 502a is too small, light will scatter, decreasing the output. Conversely, if the proportion of the projection/recess portion 502a in the size of the n-type GaN substrate 501 is too large, the region capable of obtaining optical gain will become too small. A preferred range of the projection/recess portion 502a is up to 10 μm to 50 μm from the end facet when the length of the n-type GaN substrate 501 along a side perpendicular to the end facet is 200 μm. Within such a range, light scattering is small, and the region capable of obtaining optical gain can be sufficiently secured. More preferably, the range may be up to 10 μm to 30 μm. Within such a range, a wider optical-gain obtainable region can be secured. It is found from the length of the n-type GaN substrate 501 and the upper limit of the above range that the range of the projection/recess portion 502a from the end facet within which sufficient optical gain can be secured is preferably 25% or less, more preferably 15% or less, of the length of the n-type GaN substrate 501.

The width of the ridge waveguide 508 is reduced in the region above the projection/recess portion 502a. Since the effective refractive index decreases right under the ridge waveguide 508 in the region above the projection/recess portion 502a, the light confinement factor decreases in this region to about 30% of that in the region having the beam 501a. This indicates that the electric field intensity of the active layer 505b is weak near the light-outgoing end facet and, as a result, light absorption of the active layer 505b decreases. This decreases optical damage at the time of high output and eventually promises stable high-output operation. In the meantime, the width of the ridge waveguide 508 is large in the region above the beam 501a. This permits sufficient light confinement into the active layer. In other words, this permits efficient light amplification and hence is advantageous in increasing the output of the nitride semiconductor laser.

Since the SiO₂ film 509 lies under the p-type electrode 510 in the region above the projection/recess portion 502a, no current injection is made to the vicinity of the light-outgoing end facet. At the light-outgoing end facet, where the periodicity of crystal is broken, dangling bonds exist on the surface. Therefore, if a current is injected also to the light-outgoing end facet, a leakage current may occur via such dangling bonds, resulting in heating the light-outgoing end facet. In view of this, in the structure of this embodiment, the SiO₂ film 509 is placed above the projection/recess portion 502a to avoid current injection, thereby to achieve high output.

As described above, in the fourth embodiment, by forming projections and recesses in the light-outgoing end facet-adjacent region and in the region other than the light-outgoing end facet-adjacent region so that the shapes thereof are different between the regions, the transition wavelength of the active layer right under the optical waveguide is shortened in the light-outgoing end facet-adjacent region and, conversely, increased in the region other than the light-outgoing end facet-adjacent region. Therefore, the transition wavelength of the active layer right under the optical waveguide is relatively small in the light-outgoing end facet-adjacent region compared with that in the region other than the light-outgoing end facet-adjacent region.

In this embodiment, the projection/recess portion 502a may be formed only in the light-outgoing end facet-adjacent region, and the region other than the light-outgoing end facet may have a flat surface with no projections/recesses. In this case, while the transition wavelength of the active layer is 375 nm in the light-outgoing end facet-adjacent region, it will be 403 nm in the region other than the light-outgoing end facet-adjacent region. Therefore, the transition wavelength of the active layer right under the optical waveguide structure will be relatively short in the light-outgoing end facet-adjacent region compared with that in the region other than the light-outgoing end facet-adjacent region.

### Fabrication Method of the Fourth Embodiment

FIGS. 8(a), 8(b), 9(a), and 9(b) show a fabrication method of the nitride semiconductor laser of the fourth embodiment of the present invention. The MOCVD technique is used for implementing the nitride semiconductor laser of the fourth embodiment of the present invention. The materials used are the same as those described in the first embodiment.

First, as shown in FIG. 8(a), the projection/recess portions 502a are formed on the n-type GaN substrate 501 having the (0001) plane as the principal surface. The projection/recess portions 502a are formed in parallel with the <11-20> direction. A formation method of the projection/recess portions 502a is as follows. An SiO₂ film is deposited as an dielectric mask by vapor deposition, and then a pattern is transferred to the SiO₂ film by light exposure or electron beam exposure and fluorocarbon reactive ion etching. Thereafter, the pattern is transferred from the SiO₂ film to the n-type GaN substrate 501 by chlorine-based dry etching, and then the SiO₂ film is entirely removed by hydrofluoric acid. The etched depth of the thus-formed recesses of the projection/recess portions 502a is 0.05 μm. As a result of the dry etching, the projection/recess portions 502a have rectangular projections and recesses. The recesses 502b are also formed in a similar manner, where the etching depth of the recesses 502b is 3 μm, and the width of the beam 501a between the recesses 502b is 3 μm.

Thereafter, crystal growth is performed on the structure shown in FIG. 8(a) by MOCVD. The layered structure after the crystal growth is shown in FIG. 8(b), in which, for easy understanding, a portion including the center of the element is cut away to show sections. The n-type GaN layer 503 having a thickness of 500 nm is first grown on the structure including the n-type GaN substrate 501 and the projection/recess structure.

The n-type GaN layer 503 is grown under the conditions of a growth temperature of 1000° C., a growth pressure of 200 Torr, a NH₃/TMG ratio of about 1000, and use of hydrogen as the carrier gas. The supply of the V-group material is comparatively small in this growth. At this time, the (1-101) plane is automatically exposed on the sidewalls of the projections/recesses of the projection/recess portion 502a due to plane direction dependence of the crystal growth rate. The reason for this is that, as discussed earlier, the (1-101) plane, which is constructed of nitrogen, becomes unstable under the conditions as described above, where the supply of the V-group material is comparatively small and hydrogen carrier gas having strong vapor etching property is used, resulting in decrease in growth rate. On the sidewalls of the recesses 502b, the (11-22) plane is automatically exposed as in the first embodiment.

As a result of the growth of the n-type GaN layer 503 as described above, triangular projections/recesses having (1-101) plane sidewalls are automatically formed on the rectangular projections/recesses of the underlying projection/recess portion 502a.

On the n-type GaN layer 503, grown sequentially are the n-type InGaN cladding layer (n-type cladding layer) 504 having a thickness of 50 nm, the InGaN/InGaN quantum well active layer 505, the p-type InGaN cladding layer (p-type cladding layer) 506 having a thickness of 50 nm, and the p-type GaN layer 507 having a thickness of 2 μm. The InGaN/InGaN quantum well active layer 505 is grown under the conditions of a growth temperature of 790° C., a growth pressure of 200 Torr, a NH₃/TMG ratio of about 6000, and use of nitrogen as the main ingredient of the carrier gas, which are the same as the conditions described above with reference to FIG. 1. As described above with reference to FIG. 1, the transition wavelength of the active layer 505b above the projection/recess portion 502a is short compared with that of the active layer 505a above the beam 501a.

FIG. 9(a) shows a structure with the ridge waveguide 508 formed on the structure of FIG. 8(b). Like the formation of the projection/recess structure, the chlorine-based dry etching technique is used for formation of the waveguide. That is, the ridge waveguide 508 is formed by etching the p-type GaN layer 507 into the shape as shown in FIG. 9(a).

The SiO₂ film 509 for isolation is formed over the ridge waveguide structure shown in FIG. 9(a), and the p-type electrode 510 is formed on a portion of the ridge waveguide 508 exposed in an opening formed through the SiO₂ film 509 for current injection by a liftoff technique. Note that the p-type electrode 510 is formed only right above the active layer 505a, not above the active layer 505b. The n-type electrode 511 is also formed on the back surface of the n-type GaN substrate 501. Finally, the two end facets 512a and 512b including the light-outgoing end facet are formed by a cleavage technique, to complete the nitride semiconductor laser of the present invention.

Although the active layers 505a and 505b are of the InGaN/InGaN quantum well structure in the fourth embodiment, aluminum may also be included in this structure. In this case, since it is possible to design the transition wavelength while allowing lattice matching with GaN, the degree of freedom of design of the nitride semiconductor laser can be dramatically improved.

Although the n-type electrode 511 is formed on the back surface of the n-type GaN substrate 501 in FIG. 9(b), it may be formed in the upper part of the element structure as far as it is electrically connected to the n-type GaN substrate 501. In this case, also, the effect of the present invention can be sufficiently exerted. Although the n-type substrate 501 is made of n-type GaN in this embodiment, a substrate made of a species other than GaN, such as sapphire and silicon, can also be used.

Although it is described in the fourth embodiment that the width of the ridge waveguide 508 is reduced in the region above the projection/recess portion 502a, the effect of the present invention will be sufficiently exerted even when the width is fixed along the waveguide direction. However, for achievement of further high output, it is effective to form the ridge waveguide 508 into the tapered shape.

Although the projection/recess portion 502a is formed near each of the two end facets in this embodiment, it does not necessarily exist near each end facet, but can just exist near at least one end facet serving as the light-outgoing end facet.

Although it is described in this embodiment that the projections/recesses of the projection/recess portion 502a are formed over the entire surface of the portion near the end facet, they do not necessarily exist over the entire surface, but may only exist in at least a region right under the optical waveguide structure. In this case, also, the effect of the present invention will be sufficiently exerted.

Although the projections/recesses of the projection/recess portion 502a are shown as being highly upright in FIG. 9(a), they are not necessarily so highly upright. Because, in the crystal growth of the n-type GaN layer 503, the (1-101) plane is automatically exposed depending on the crystal growth conditions used, and as a result, triangular projections/recesses are formed. To expose the (1-101) plane preferentially, a low growth pressure, a high ammonia partial pressure, use of hydrogen carrier gas, and a high growth temperature are necessary.

### INDUSTRIAL APPLICABILITY

According to the nitride semiconductor laser of the present invention, the characteristics in crystal growth of nitride semiconductors are actively used to achieve high output operation without incurring increase of complicated processes and cost increase.

1-24. (canceled)

25. A nitride semiconductor laser, comprising:
a substrate;
a dielectric film formed on the substrate;
a semiconductor multilayer film including an active layer, formed on the substrate and the dielectric film; and
an optical waveguide structure formed on the active layer and placed between two end facets including a light-outgoing end facet,
wherein
the dielectric film has an opening in which a surface of the substrate is exposed, formed to extend along the optical waveguide, and
the width of the opening of the dielectric film is larger in a light-outgoing end facet-adjacent region than in a region other than the light-outgoing end facet-adjacent region,
or no dielectric film exists in the light-outgoing end facet-adjacent region.

26. The nitride semiconductor laser of claim 25, wherein
at an interface between a semiconductor layer of the semiconductor multilayer film immediately underlying the active layer and the active layer, a plane direction is different between the light-outgoing end facet-adjacent region and the region other than the light-outgoing end facet-adjacent region.

27. The nitride semiconductor laser of claim 26, wherein
the active layer has a multiple quantum well structure including a well layer and a barrier layer, and at least the well layer is a nitride semiconductor including indium.

28. The nitride semiconductor laser of claim 27, wherein
the indium content of the well layer right under the optical waveguide structure is smaller in the light-outgoing end facet-adjacent region than in the region other than the light-outgoing end facet-adjacent region.

29. The nitride semiconductor laser of claim 27, wherein
the thickness of the well layer right under the optical waveguide structure is smaller in the light-outgoing end facet-adjacent region than in the region other than the light-outgoing end facet-adjacent region.

30. The nitride semiconductor laser of claim 25, wherein
the semiconductor multilayer film is of a trapezoidal structure of which a section taken along a plane parallel to the end facets is trapezoidal and a top surface is flat.

31. The nitride semiconductor laser of claim 30, wherein
the width of the top surface of the trapezoidal structure is larger in the light-outgoing end facet-adjacent region than in the region other than the light-outgoing end facet-adjacent region.

32. The nitride semiconductor laser of claim 25, wherein
sidewalls of a semiconductor layer of the semiconductor multilayer film immediately underlying the active layer are constructed of (11-22) plane.

33. A nitride semiconductor laser, comprising:
a substrate;
a projection/recess structure formed on the substrate;
a semiconductor multilayer film including an active layer, formed on the substrate and the projection/recess structure; and
an optical waveguide structure formed on the active layer and placed between two end facets including a light-outgoing end facet,
wherein
the projection/recess structure exists only in the light-outgoing end facet-adjacent region, and the substrate is flat with no projections/recesses in the region other than the light-outgoing end facet-adjacent region.

34. The nitride semiconductor laser of claim 33, wherein
the projection/recess structure includes stripes, and the direction of the stripes is roughly parallel to a light propagation direction.

35. The nitride semiconductor laser of claim 33, wherein
the projection/recess structure includes stripes, and the direction of the stripes is roughly perpendicular to a light propagation direction.

36. The nitride semiconductor laser of claim 33, wherein
a light confinement factor of the optical waveguide structure is smaller in the light-outgoing end facet-adjacent region than in the region other than the light-outgoing end facet-adjacent region.

37. The nitride semiconductor laser of claim 33, wherein
the projection/recess structure exists under a region having no optical waveguide structure, and the substrate under a region having the optical waveguide structure is flat.

38. The nitride semiconductor laser of claim 25, wherein
a plane direction of a top surface of the semiconductor multilayer film matches with a plane direction of the principal surface of the substrate.

39. The nitride semiconductor laser of claim 38, wherein
the plane direction of the top surface of the semiconductor multilayer film in the light-outgoing end facet-adjacent region is inclined from the plane direction of the substrate toward a plane direction of the light-outgoing end facet.

40. The nitride semiconductor laser of claim 39, wherein
the plane direction of the top surface of the semiconductor multilayer film in the light-outgoing end facet-adjacent region is inclined by six degrees or less from the plane direction of the substrate toward the plane direction of the light-outgoing end facet.

41. The nitride semiconductor laser of claim 25, wherein
the principal surface of the substrate is (0001) plane.

42. The nitride semiconductor laser of claim 25, wherein
the principal surface of the substrate is (11-20) plane.

43. The nitride semiconductor laser of claim 25, wherein
no electrode exists right above the light-outgoing end facet-adjacent region.

44. The nitride semiconductor laser of claim 33, wherein
a plane direction of a top surface of the semiconductor multilayer film matches with a plane direction of the principal surface of the substrate.

45. The nitride semiconductor laser of claim 33, wherein
the principal surface of the substrate is (0001) plane.

46. The nitride semiconductor laser of claim 33, wherein
the principal surface of the substrate is (11-20) plane.

47. The nitride semiconductor laser of claim 33, wherein
no electrode exists right above the light-outgoing end facet-adjacent region.
